(19) United States
(12) Patent Application Publication
(10) Pub. No.: US 2016/0149122 A1
(43) Pub. Date: May 26, 2016

(54) Methods For Fabricating Magnetic Devices And Associated Systems And Devices

(71) Applicant: THE TRUSTEES OF DARTMOUTH COLLEGE, Hanover, NH (US)

(72) Inventors: Charles R. Sullivan, West Lebanon, NH (US); Daniel V. Harburg, Hanover, NH (US); Christopher G. Levey, Thetford Center, VT (US); Song Yue, West Lebanon, NH (US)

(21) Appl. No.: 14/898,367

(22) PCT Filed: Jun. 13, 2014
(86) PCT No.: PCT/US14/42403

§ 371 Date: Dec. 14, 2015

Related U.S. Application Data
(60) Provisional application No. 61/835,212, filed on Jun. 14, 2013.

(51) Int. Cl. H01L 43/12; G03F 1/68; H01L 43/02

(52) U.S. Cl. CPC H01L 43/12; H01L 43/02; G03F 1/68

(57) ABSTRACT

A method for exposing a photoresist material to light includes the following steps: (1) optically coupling the light to an optical mask via a prism and a first liquid layer joining the prism and the optical mask, (2) masking the light using the optical mask, and (3) optically coupling the masked light to the photoresist material. The method is used, for example, to fabricate a magnetic device on a semiconductor substrate. A hybrid semiconductor and magnetic device includes a semiconductor substrate and a top insulating structure deposited on an outer surface of the semiconductor substrate. The top insulating structure has opposing first and second sloping sidewalls, where each sloping sidewall forms an acute angle of at least 30 degrees, relative to an axis normal to the outer surface of the semiconductor substrate. The hybrid semiconductor and magnetic device further includes a magnetic core surrounding the top insulating structure.

### RELATED APPLICATIONS

This Application claims benefit of priority to U.S. Provisional Patent Application No. 61/835,212, filed Jun. 14, 2013, which is incorporated herein by reference.

### GOVERNMENT RIGHTS

This invention was made with government support under contract number DE-AR0000123 awarded by the Department of Energy Advanced Research Project Agency. The government has certain rights in the invention.

### BACKGROUND

Magnetic devices, such as inductors and transformers, are used in many applications, including power conversion applications. For example, inductors are widely used in switching power converters to store energy, and transformers are widely used in power converters to transform a voltage level and/or to provide electrical isolation.

The integration and miniaturization of magnetic devices has become a major focus of the power electronics community as the demand for high-performance, low-volume converters has grown. For example, small and efficient power converters can increase the penetration of energy-saving technologies, such as light emitting diode (LED) lighting, by decreasing system costs and by increasing performance and efficiency. Magnetic devices, however, are generally the largest and most lossy elements in miniature power converters.

It has been proposed to integrate miniature magnetic devices in semiconductor substrates, thereby potentially realizing a single-chip power converter. However, conventional miniature magnetic devices suitable for such integration have drawbacks. For example, it has been proposed to form a single-turn V-groove inductor in a silicon substrate. While this inductor is potentially well suited for low-voltage, high-current power conversion applications, its inductance value is typically too low for LED lighting applications, or other applications requiring large inductance values.

As another example, it has been proposed to form multi-turn inductors in deep anisotropically-etched trenches of semiconductor substrates, where the trench sidewalls form magnetic core sidewalls. Although these inductors potentially achieve significant advantages, it can be challenging to form magnetic devices in deep trenches of semiconductor substrates.

### SUMMARY

In an embodiment, a method for exposing a photoresist material to light includes the following steps: (1) optically coupling the light to an optical mask via a prism and a first liquid layer joining the prism and the optical mask; (2) masking the light using the optical mask; and (3) optically coupling the masked light to the photoresist material.

In an embodiment, a method for fabricating a magnetic device on a semiconductor substrate includes the following steps: (1) depositing a base layer of magnetic material on the semiconductor substrate; (2) patterning a base insulating layer on the base layer of magnetic material; (3) patterning a winding on the base insulating layer; (4) optically coupling light to an optical mask via a prism and a first liquid layer joining the prism and the optical mask; (5) masking the light using the optical mask; (6) optically coupling the masked light to photoresist material disposed on the winding; (7) developing the photoresist material to yield a top insulating structure; and (8) depositing a top layer of magnetic material on the top insulating structure.

In an embodiment, a hybrid semiconductor and magnetic device includes a semiconductor substrate and a top insulating structure deposited on an outer surface of the semiconductor substrate. The top insulating structure has opposing first and second sloping sidewalls, where each sloping sidewall forms an acute angle of at least 30 degrees, relative to an axis normal to the outer surface of the semiconductor substrate. The hybrid semiconductor and magnetic device further includes a magnetic core surrounding the top insulating structure.

### BRIEF DESCRIPTION OF THE DRAWINGS

FIG. 1 illustrates a method for fabricating a magnetic device, according to an embodiment.

FIGS. 2 and 3 are top plan and cross-sectional views, respectively, of two base layers of magnetic material deposited on a semiconductor substrate, according to an embodiment.

FIGS. 4 and 5 are top plan and cross-sectional views, respectively, of the device of FIGS. 2 and 3 with a base insulating layer patterned on the device, according to an embodiment.

FIGS. 6 and 7 are top plan and cross-sectional views, respectively, of the device of FIGS. 4 and 5 with a winding patterned on the base insulating layer, according to an embodiment.

FIGS. 8 and 9 are top plan and cross-sectional views, respectively, of the device of FIGS. 6 and 7 with a top insulating structures patterned on the winding, according to an embodiment.

FIGS. 10 and 11 are top plan and cross-sectional views, respectively, of the device of FIGS. 8 and 9 with a top layer of magnetic material deposited on the top insulating structures, according to an embodiment.

FIG. 12 illustrates a method for exposing a photoresist material to light, according to an embodiment.

FIGS. 13 and 14 are cross-sectional views illustrating use of the FIG. 12 method, according to an embodiment.

FIG. 15 illustrates another method for fabricating a magnetic device, according to an embodiment.

FIGS. 16 and 17 are top plan and cross-sectional views, respectively, of a semiconductor substrate with a trench etched therein, according to an embodiment.

FIGS. 18 and 19 are top plan and cross-sectional views, respectively, of the device of FIGS. 16 and 17 with a base layer of magnetic material deposited in the trench of the semiconductor substrate, according to an embodiment.

FIGS. 20 and 21 are top plan and cross-sectional views, respectively, of the device of FIGS. 18 and 19 with a base insulating layer deposited in the trench of the semiconductor substrate, according to an embodiment.

FIGS. 22 and 23 are top plan and cross-sectional views, respectively, of the device of FIGS. 20 and 21 with a winding patterned on the insulating layer, according to an embodiment.

FIGS. 24 and 25 are top plan and cross-sectional views, respectively, of the device of FIGS. 22 and 23 with top insulating structures deposited on the winding, according to an embodiment.

FIGS. 26 and 27 are top plan and cross-sectional views, respectively, of the device of FIGS. 24 and 25 after a top layer of magnetic material has been deposited on the top insulating structures of the device, according to an embodiment.

FIGS. 28 and 29 are top plan and cross-sectional views, respectively, of the device of FIGS. 8 and 9 with a top layer of magnetic material deposited on the top insulating structures and extraneous magnetic material on the semiconductor substrate, according to an embodiment.

FIG. 30 illustrates yet another method for fabricating a magnetic device, according to an embodiment.

FIGS. 31 and 32 are top plan and cross-sectional views, respectively, of two base layers of magnetic material deposited on a semiconductor substrate, according to an embodiment.

FIGS. 33 and 34 are top plan and cross-sectional views, respectively, of the device of FIGS. 31 and 32 with a base insulating layer patterned on the device, according to an embodiment.

FIGS. 35 and 36 are top plan and cross-sectional views, respectively, of the device of FIGS. 33 and 34 with a winding patterned on the base insulating layer, according to an embodiment.

FIGS. 37 and 38 are top plan and cross-sectional views, respectively, of the device of FIGS. 35 and 36 with top insulating structures and shading structures patterned on the winding and substrate, according to an embodiment.

FIGS. 39 and 40 are top plan and cross-sectional views, respectively, of the device of FIGS. 37 and 38 with a top layer of magnetic material deposited on the top insulating structures, according to an embodiment.

FIG. 41 illustrates a method for removing extraneous magnetic material, according to an embodiment.

FIG. 42 is cross-sectional view of a device similar to that of FIG. 29, but with photoresist applied to top layers of magnetic material, according to an embodiment.

FIG. 43 is a cross-sectional view of the FIG. 42 device after extraneous magnetic material has been removed, according to an embodiment.

FIG. 44 is a cross-sectional view of the FIG. 42 device after photoresist has been removed, according to an embodiment.

### DETAILED DESCRIPTION OF THE EMBODIMENTS

Applicants have developed methods and systems for fabricating a magnetic device, such as an inductor or a transformer, on a semiconductor substrate surface, or protruding from a semiconductor substrate surface. These methods and systems help minimize the number of fabrication steps and also promote forming high quality magnetic cores.

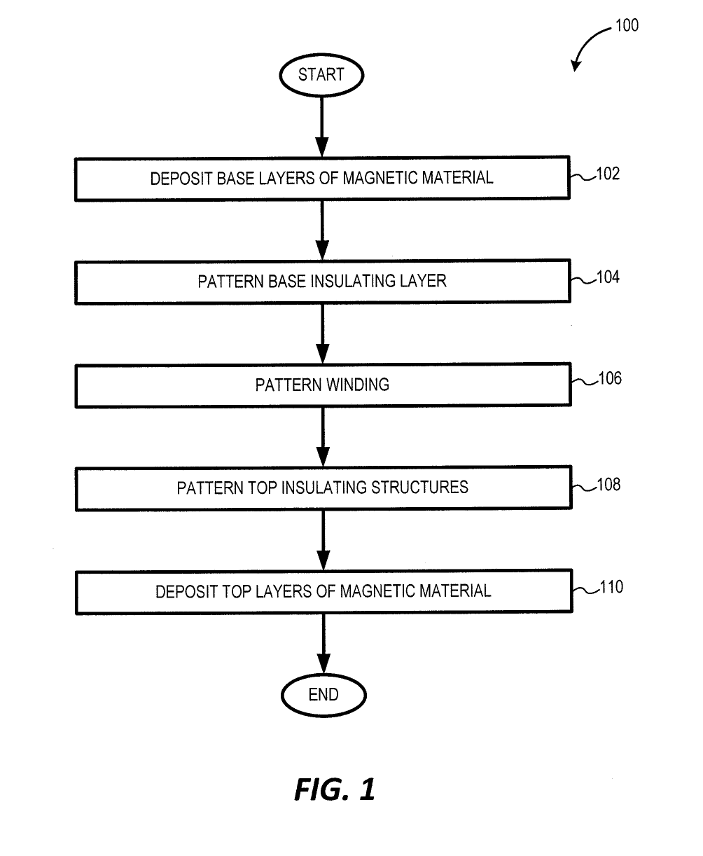

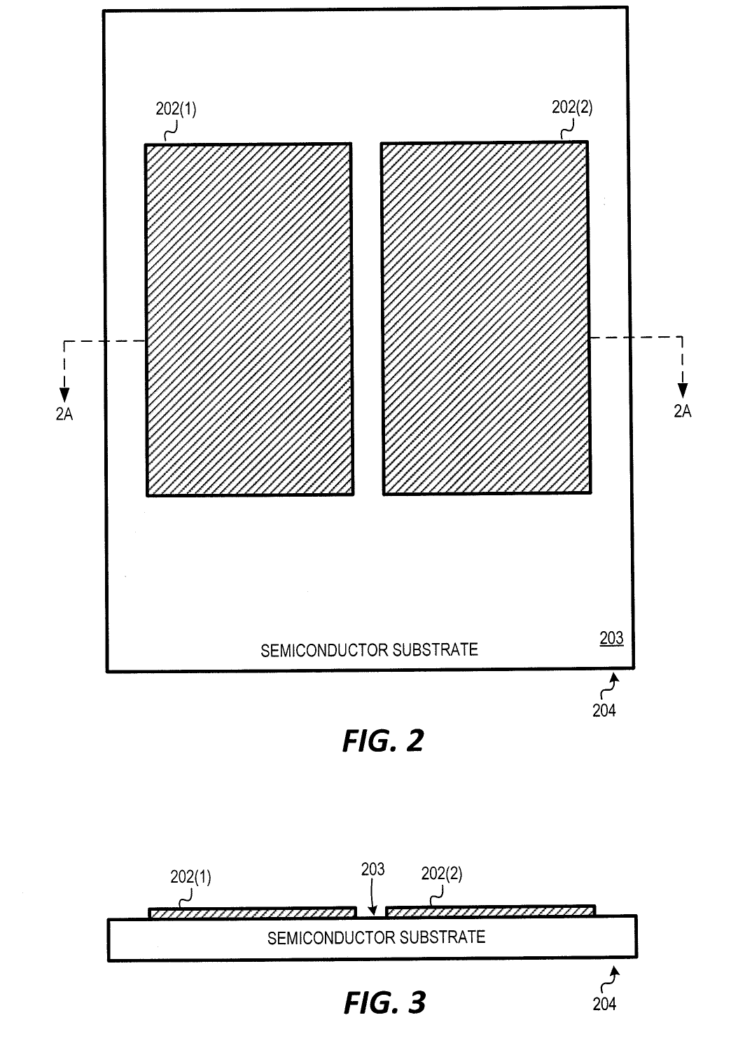

FIG. 1 illustrates a method 100 for fabricating a magnetic device, such as an inductor or a transformer, on a semiconductor substrate surface, to form a hybrid semiconductor and magnetic device. FIGS. 2-11 illustrate one example of an inductor fabricated according to method 100. This inductor has a “racetrack” shape and includes two magnetic cores surrounding the inductor's winding. It should be understood, however, that method 100 could be used to fabricate magnetic devices other than the inductor illustrated in FIGS. 2-11. For example, method 100 could be used to fabricate an inductor having a different number of magnetic cores or an inductor having a different shape. As another example, method 100 could be used to fabricate a magnetic device having multiple windings, such as a transformer.

In step 102 of method 100, a base layer of magnetic material is deposited on the semiconductor substrate for each magnetic core. In one example of step 102, two base layers 202 of magnetic material are deposited on an outer surface 203 of a semiconductor substrate 204 as illustrated in FIG. 2, such as by reactively sputtering a magnetic material through a shadow mask onto semiconductor substrate 204. Each base layer 202 will ultimately form the base of a respective magnetic core. The magnetic material is deposited, for example, in the presence of a uniaxial magnetic field to align the material's magnetic domains, such that the magnetic material has anisotropic magnetic properties, to help minimize magnetic hysteresis losses. Semiconductor substrate 204 is typically opaque to ultraviolet light. In some embodiments, semiconductor substrate 204 is a silicon substrate, and the magnetic material forming base layers 202 of magnetic material is a cobalt-zirconium-oxygen (Co—Zr—O) material having a thickness of approximately 20 microns. Semiconductor substrate 204 optionally includes one or more electronic components, such as power transistors and/or control logic. Thus, in certain embodiments, semiconductor substrate 204 and the inductor formed thereon form part or all of a switching power converter, thereby potentially achieving a monolithically integrated power converter. FIG. 3 shows a cross-sectional view taken along line 2A-2A of the FIG. 2 top plan view. In this document, specific instances of an item may be referred to by use of a numeral in parentheses (e.g., base layer 202(1)) while numerals without parentheses refer to any such item (e.g., base layers 202).

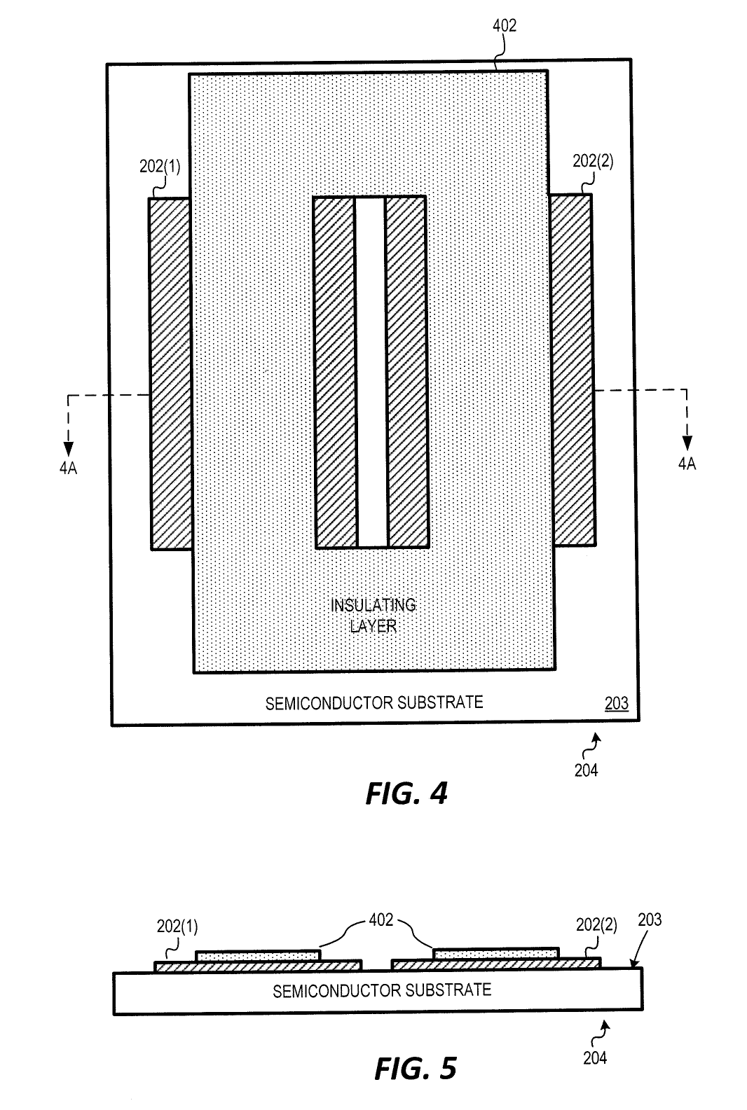

In step 104, a base insulating layer of photoresist material is patterned, i.e., formed to achieve a desired pattern, on the base layers of magnetic material and on the semiconductor substrate. The base insulating layer insulates an electrically conductive winding, which is patterned in subsequent step 106, from the base layers of magnetic material and from the semiconductor substrate. In one example of step 104, an insulating layer 402 is patterned on base magnetic material layers 202 and on outer surface 203 of semiconductor substrate 204, as illustrated in FIG. 4. FIG. 5 is a cross-sectional view taken along line 4A-4A of the FIG. 4 top plan view. In some embodiments, insulating layer 402 is a 20 micron thick layer of SU-8 3010 photoresist material.

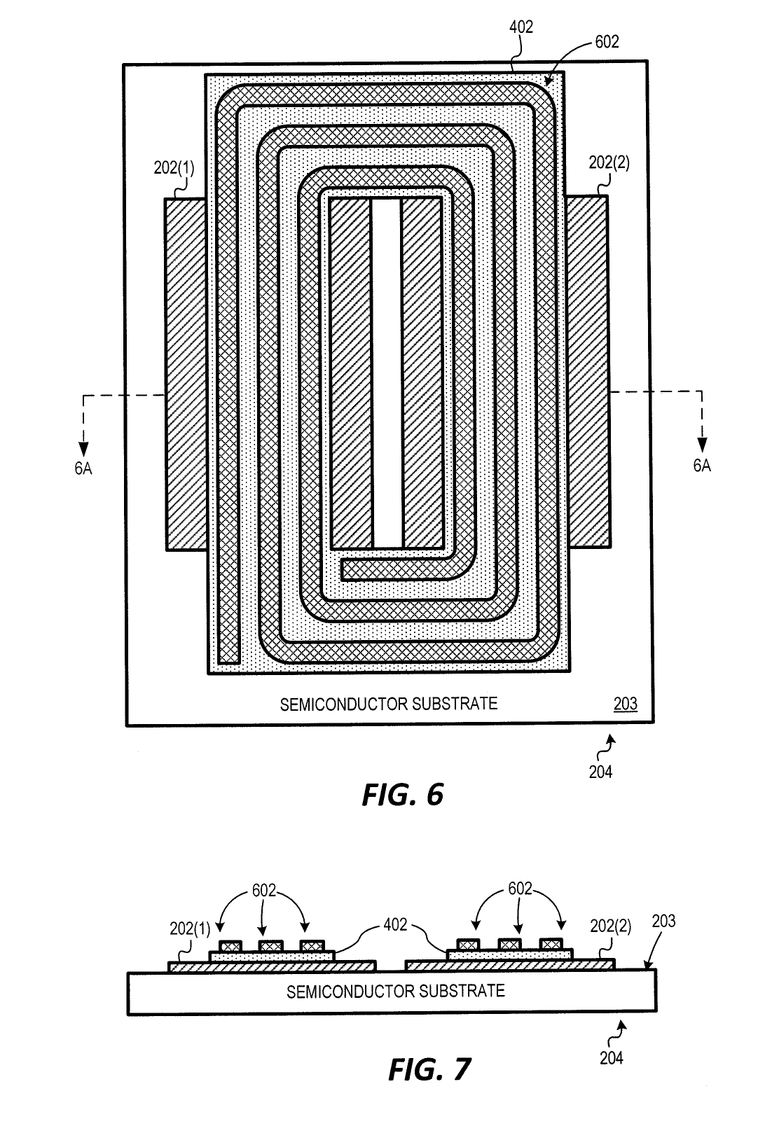

In step 106, an electrically conductive winding is patterned on the base insulating layer. In one example of step 106, an electrically conductive winding 602 is patterned on insulating layer 402, as illustrated in FIG. 6, such as by electroplating copper through a NR-21-20000P negative photoresist mold. In some embodiments, winding 602 is 40 microns thick with 15 micron gaps between winding turns. Although winding 602 is shown as forming three turns, winding 602 could form a different number of turns, and/or have a different shape, without departing from the scope hereof. Additionally, in some alternate embodiments, two or more windings are formed on the insulating layer in step 106, such as to form a transformer. FIG. 7 is a cross-sectional view taken along line 6A-6A of the FIG. 6 top plan view.

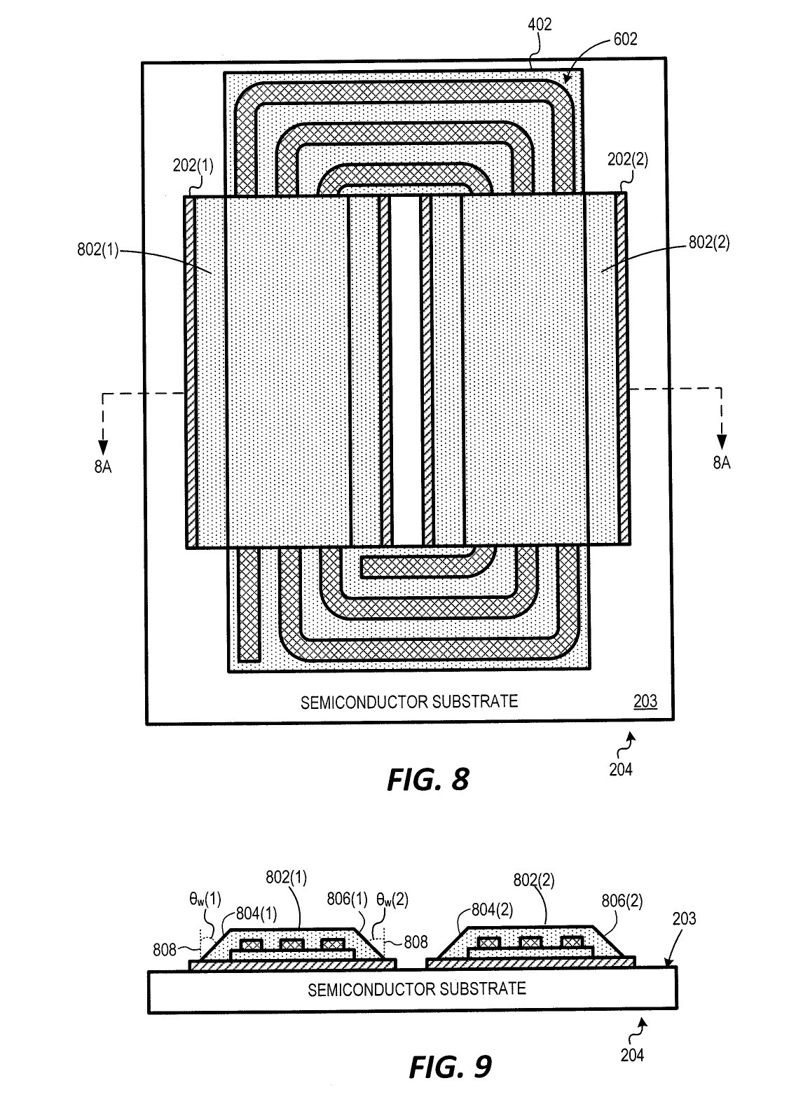

In step 108, a top insulating structure of photoresist material is patterned over each base layer of magnetic material using a prism-assisted, ultra-violet light emitting diode (LED) photolithography procedure, to insulate the winding from a top layer of magnetic material disposed in a subsequent step. In one example of step 108, top insulating structures 802 having opposing sloping sidewalls 804, 806 which are patterned on winding 602 over base layers 202 of magnetic material, as illustrated in FIG. 8. FIG. 9 is a cross-sectional view taken along line 8A-8A of the FIG. 8 top plan view. Each sidewall 804, 806 has a respective acute angle θw relative to an axis 808 normal to outer surface 203. In some embodiments, each angle θw is at least 30 degrees to facilitate subsequent sputter deposition of high quality magnetic material on sidewalls 804, 806. As discussed further below, use of a prism-assisted, ultra-violet LED exposure method helps achieve relatively large values of angles θw.

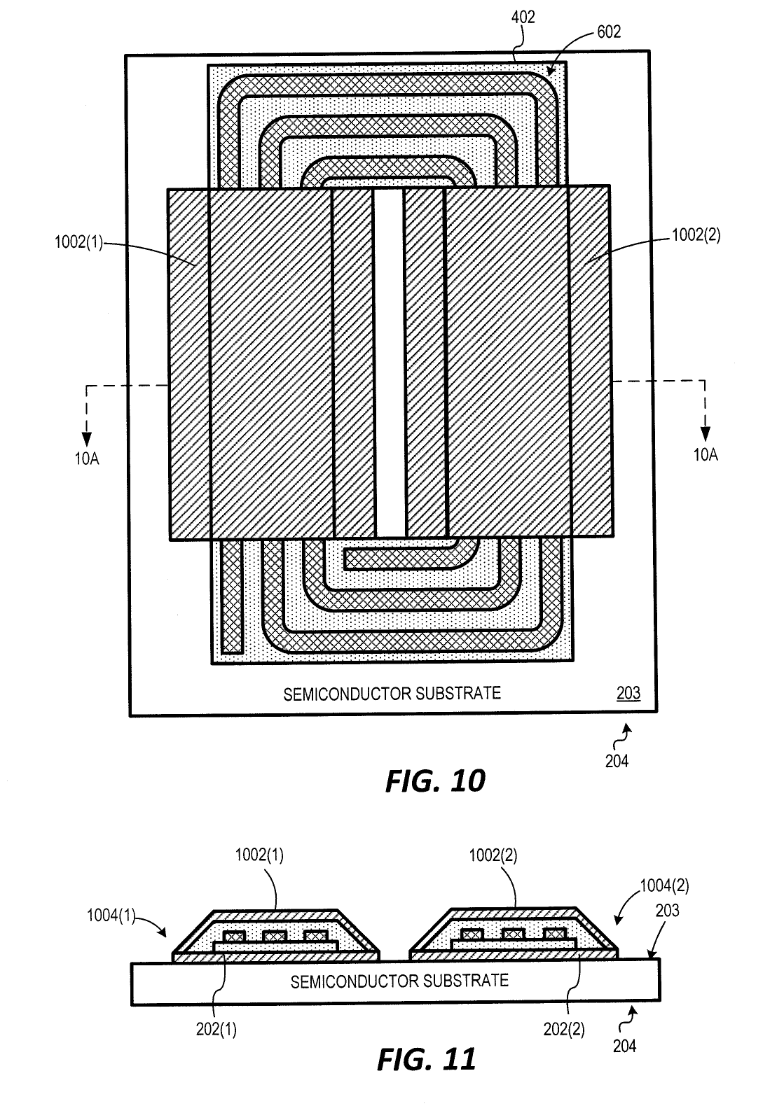

In step 110, a top layer of magnetic material is deposited on each top insulating structure, such that the base layer of magnetic material and the top layer of magnetic material collectively form a magnetic core surrounding the winding. In one example of step 110, a respective top magnetic layer 1002 is deposited on each top insulating structure 802, such as by sputtering the magnetic material through a shadow mask onto the photoresist structure, as illustrated in FIG. 10. FIG. 11 is a cross-sectional view taken along line 10A-10A of the FIG. 10 top plan view. Base magnetic material layer 202(1) and top magnetic material layer 1002(1) collectively form a first magnetic core 1004(1), and base magnetic material layer 202(2) and top magnetic material layer 1002(2) collectively form a second magnetic core 1004(2). Each magnetic core 1004 surrounds a portion of winding 602. Although magnetic cores 1004 are shown as being separated from each other, in some alternate embodiments, magnetic material joins magnetic cores 1004, such as along semiconductor substrate 204 outer surface 203. In some embodiments, the magnetic material forming top magnetic material layers 1002 is a Co—Zr—O material.

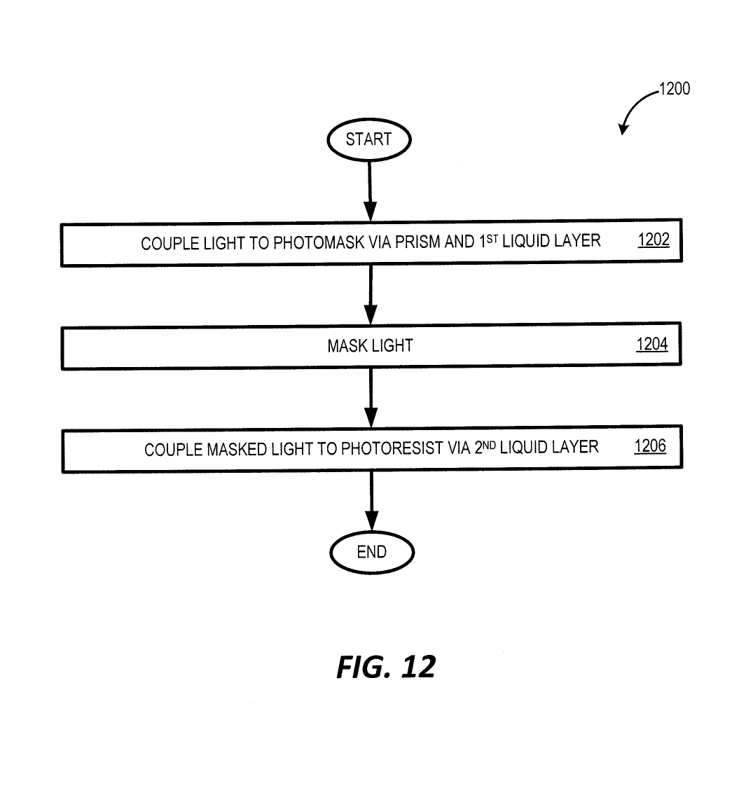

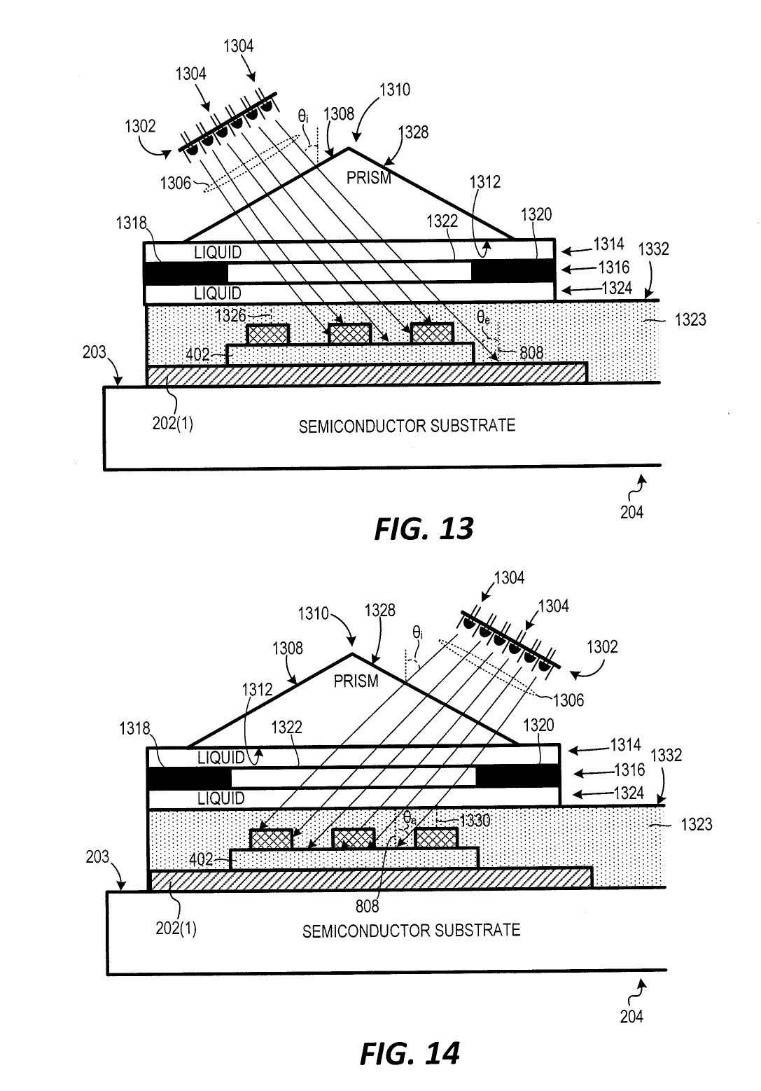

Patterning step 108 includes an ultra-violet LED photolithography procedure, as discussed above. This procedure includes exposing a photoresist material deposited on the winding to light through an optical mask, to transfer a geometric pattern of the optical mask to the photoresist layers. The photoresist layers are then developed to yield top insulating structures corresponding to the optical mask's geometric pattern. FIG. 12 illustrates a method 1200 for exposing photoresist material to light, which is used, for example, in patterning step 108. Method 1200 is illustrated in FIGS. 12 and 13 in the context of forming top insulating structures 802 of FIGS. 8 and 9. It should be understood, however, that method 1200 is not limited to such application.

In step 1202, light is optically coupled to an optical mask via a prism and a first liquid layer joining the prism and the optical mask. In one example of step 1202 illustrated in FIG. 13, a LED array 1302 includes a plurality of LEDs 1304 generating ultra-violet (UV) light 1306. In some embodiments, LEDs 1304 generate light having a wavelength of 380 nanometers. While FIG. 13 only shows several LEDs 1304 in LED array 1302 to promote illustrative clarity, LED array 1302 will typically include a large number of LEDs 1304, such as one hundred LEDs 1304, so that UV light 1306 is sufficiently strong for photolithography. LED array 1302 is disposed proximate to a first face 1308 of a prism 1310, such that UV light 1306 is projected on prism first face 1308. Prism 1310 is, for example, a right angle prism. UV light 1306 travels through prism 1310 and exits a second face 1312 of the prism. A first liquid layer 1314 joins an optical mask 1316 to prism second face 1312, and UV light 1306 travels through first liquid layer 1314 to optical mask 1316. First liquid layer 1314, which in some embodiments is water, prevents an air gap from forming between prism 1310 and an optical mask 1316, thereby reducing reflection and refraction of UV light 1306.

In step 1204, the light is masked using the optical mask, such that the photoresist material is patterned by masked light according to a geometric pattern of the optical mask. In one example of step 1204 illustrated in FIG. 13, UV light 1306 is masked by optical mask 1316, which includes opaque portions 1318, 1320 and a transparent portion 1322 forming a geometric pattern. Optical mask 1316 blocks UV light 1306 incident on opaque portions 1318, 1320, and optical mask 1316 transmits UV light 1306 incident on transparent portion 1322, thereby masking UV light 1306 according to the geometric pattern of optical mask 1316.

In step 1206, the masked light is optically coupled from the optical mask to the photoresist material via a second liquid layer joining the optical mask and the photoresist material, thereby patterning the photoresist material according to the optical mask's geometric pattern. In one example of step 1206 illustrated in FIG. 13, UV light 1306 is optically coupled to a photoresist layer 1323 and base insulating layer 402 via a second liquid layer 1324 joining optical mask 1316 to photoresist layer 1323. Photoresist layer 1323 is, for example, a 60 micron thick layer of SU-8 3050 negative photoresist material deposited on winding 602. Second liquid layer 1324, which in some embodiments is water, prevents an air gap from forming between optical mask 1316 and photoresist layer 1323, thereby reducing reflection and refraction of UV light 1306. In some other embodiments, second liquid layer 1324 is an oil, such as sunflower oil, which has a lower surface tension than water, while first liquid layer 1314 is water. Such configuration allows photoresist layer 1323 and semiconductor substrate 204 to be aligned relative to optical mask 1316 without changing alignment of prism 1310 with respect to optical mask 1316. Photoresist layer 1323 is developed after exposure to UV light 1306 to form top insulating structures 802 of FIGS. 8 and 9.

In some alternate embodiments where the photoresist material is sufficiently flat, or where the photoresist material is compressed when adjoining the optical mask, the second liquid layer is omitted and the optical mask directly contacts the photoresist material. For example, second liquid layer 1324 is optionally omitted and optical mask 1316 directly contacts photoresist layer 1323 in certain embodiments where an outer surface 1332 of photoresist material 1323 is sufficiently flat, or where optical mask compresses 1316 photoresist material 1323.

A single execution of steps 1202-1206 results in only a portion of the photoresist material being exposed, due to use of prism 1310. For example, only portions of insulating layer 402 and photoresist layer 1323 to the right of dashed line 1326 are exposed to UV light 1306 in the FIG. 13 example. It is often necessary, however, to expose additional portions of the photoresist material to light to achieve a desired three-dimensional structure. Accordingly, steps 1202-1206 are optionally repeated with the light source incident on a different face of the prism, to expose additional portions of the photoresist material to light, before developing the photoresist material. For example, FIG. 14 illustrates an example with steps 1202-1206 executed with LED array 1302 moved such that UV light 1306 is incident on a third face 1328 of prism 1310, such that portions of insulating layer 402 and photoresist layer 1323 to the left of dashed line 1330 are exposed to UV light 1306.

Certain alternate embodiments of method 1200 use two light sources to simultaneously project light on two different faces of the prism, thereby speeding photoresist material exposure. For example, in one alternate embodiment, steps 1202-1206 are executed concurrently using two LED arrays 1302, where one of the LED arrays is configured to project UV light on first face 1308 as illustrated in FIG. 13, and the other LED array is configured to project UV light on third face 1328 as illustrated in FIG. 14, such that UV light 1306 is simultaneously projected on both first face 1308 and third face 1328.

Method 1200 is executed for each top insulating structure to be patterned. For example, in one embodiment of method 100 (FIG. 1), method 1200 is executed twice in patterning step 108, once for patterning top insulating structure 802(1), and once for patterning top insulating structure 802(2).

Use of prism 1310 and liquid layers 1314, 1324 to optically couple UV light 1306 to insulating layer 402 and photoresist layer 1323 potentially enables obtaining a large exposure angle θe with substrates opaque to UV light, where the exposure angle is an acute angle at which UV light 1306 penetrates photoresist layer 1323, relative to axis 808 normal to semiconductor substrate 204 outer surface 203. For example, in a particular embodiment, prism 1310, liquid layers 1314, 1324, optical mask 1316, insulating layer 402, and photoresist layer 1323 are chosen to have refractive indices specified in TABLE 1 below, resulting in an exposure angle θe of 45 degrees, when angle of incidence θi of UV light 1306 on prism first face 1308 is 37.3 degrees. The configuration specified in TABLE 1 also results in a relatively large percentage (85 percent) of UV light 1306 reaching insulating layer 402 and photoresist layer 1323, neglecting light blocked by optical mask 1316. A different exposure angle θe could be obtained, for example, by varying angle of incidence θi and/or by changing the index of refraction of one or more of prism 1310, liquid layers 1314, 1324, optical mask 1316, insulating layer 402, and photoresist layer 1323.

TABLE 1

| | | Beam Angle | Percentage of Total |
|---|---|---|---|
| | Index of | (deg.) (from | Power Transmitted |
| Medium | Refraction | normal axis) | Through Medium |
| Air | 1.00 | 37.3 | 100 |
| Prism 1310 | 1.53 | 50.0 | 96 |
| 1^{st} Liquid Layer 1314 | 1.34 | 61.0 | 93 |
| Optical Mask 1316 | 1.53 | 50.0 | 91 |
| 2^{nd} Liquid Layer | 1.34 | 61.0 | 89 |
| 1324 | | | |
| Insulating Layer 402, | 1.65 | 45.0 | 85 |
| Photoresist Layer | | | |
| 1323 | | | |

Large exposure angles θe enable top insulating structures obtained after development to have large sidewall angles. For example, use of method 1200 in step 108 of method 100 may enable top insulating structure 802 sidewall angles θw to be relatively large acute angles, such as 30 degrees or larger. Large sidewall angles, in turn, facilitate sputtering of high quality magnetic material on the sidewalls, such as during step 110 of method 100. In particular, Applicants have found sidewall angles θw to be critical when sputtering magnetic material on the sidewalls. If the angles are too small, such as less than 30 degrees, magnetic properties of the magnetic material sputtered onto the sidewalls will be degraded, resulting in impaired performance.

It should be appreciated that it may be difficult, or even impossible, to obtain large exposure angles using conventional photolithography exposure techniques. For example, the conventional technique of titling a substrate stage can obtain only limited exposure angles, due to refractive index mismatch. While such problem can potentially be overcome by immersing the photoresist, a substrate tilting apparatus, and an optical mask in an index matching liquid, the immersion process is cumbersome and precludes simple optical mask alignment techniques. As another example, while conventional “backside” photolithography exposure techniques can sometimes yield large exposure angles, such techniques are not feasible in applications where the substrate is opaque, because backside exposure techniques require that light pass through the substrate. Semiconductor substrates are typically opaque, thereby inhibiting use of backside exposure techniques.

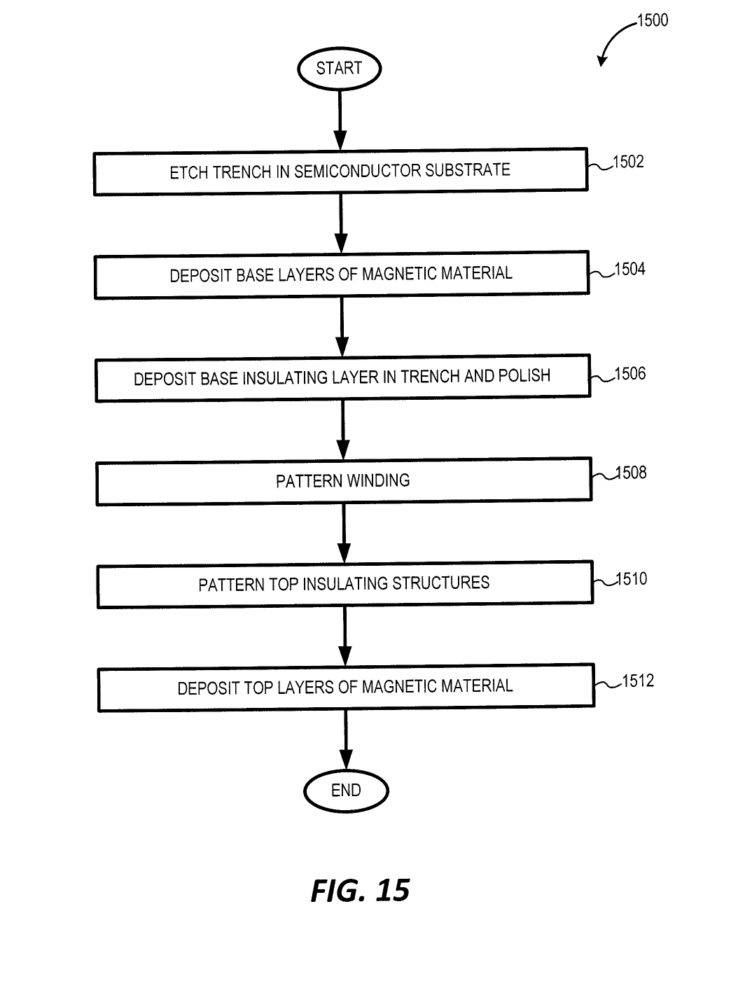

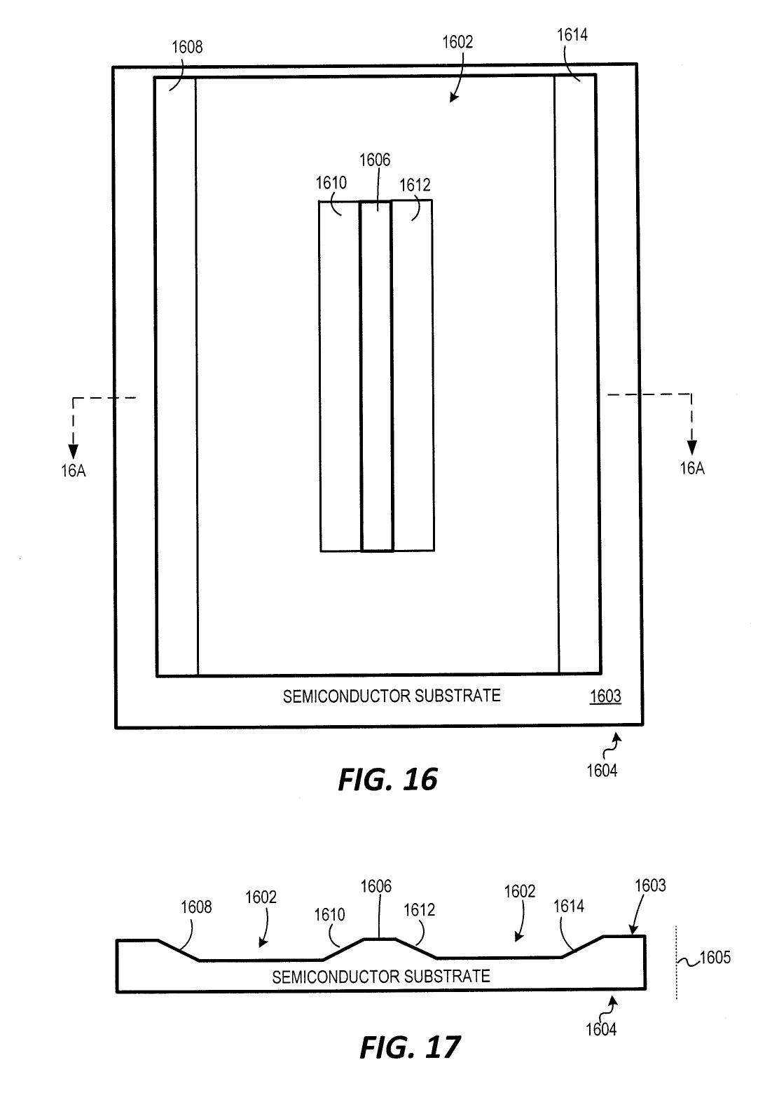

FIG. 15 illustrates another method 1500 for fabricating a magnetic device, such as an inductor or a transformer, on a semiconductor substrate, to form a hybrid semiconductor and magnetic device. Method 1500 is similar to method 100 of FIG. 1, but method 1500 results in the magnetic device protruding from a surface of the semiconductor substrate. FIGS. 16-27 illustrate one example of an inductor being fabricated according to method 1500. The inductor has a racetrack shape and includes two magnetic cores surrounding the inductor's winding. It should be understood, however, that method 1500 could be used to fabricate magnetic devices other than the inductor of FIGS. 16-27. For example, method 1500 could be used to fabricate an inductor having a different number of magnetic cores or an inductor having a different shape. As another example, method 1500 could be used to fabricate a magnetic device having multiple windings, such as a transformer.

In step 1502, a trench is etched in a semiconductor substrate. In one example of step 1502 illustrated in FIG. 16, a trench 1602 is anisotropically etched in a semiconductor substrate 1604 which is, for example, a silicon substrate. Semiconductor substrate 1604 is typically opaque to UV light. Trench 1602 extends from an outer surface 1603 of semiconductor substrate 1604 partially through the substrate, along an axis 1605 normal to outer surface 1603. Trench 1602 has a racetrack shape and surrounds an un-etched center portion 1606 of semiconductor substrate 1604. Trench 1620 typically has sloping sidewalls 1608, 1610, 1612, 1614. FIG. 17 is a cross-sectional view taken along line 16A-16A of the FIG. 16 top plan view. Semiconductor substrate 1604 optionally includes one or more electronic components, such as power transistors and/or control logic. Thus, in certain embodiments, semiconductor substrate 1604 and the inductor formed thereon form part or all of a switching power converter, thereby potentially achieving a monolithically integrated power converter.

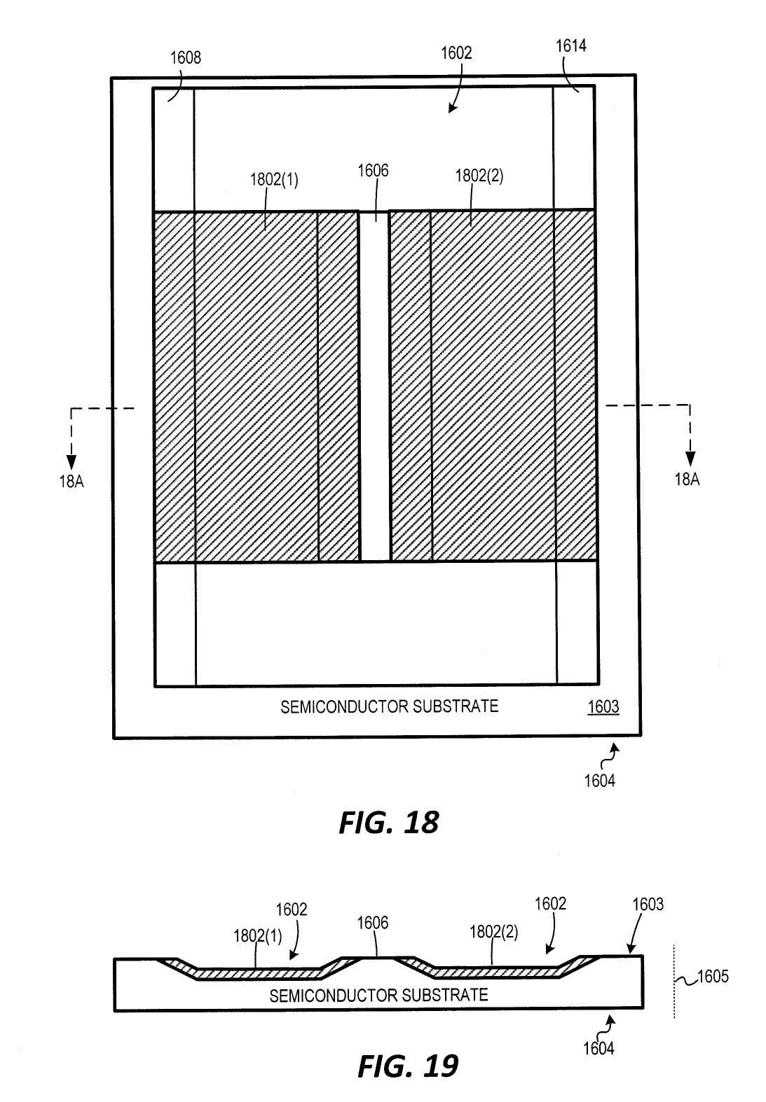

In step 1504, a base layer of magnetic material is deposited in the semiconductor substrate trench for each magnetic core. In some embodiments, the magnetic material extends beyond the trench and onto an outer surface of the semiconductor substrate. In one example of step 1504 illustrated in FIG. 18, two base magnetic material layers 1802 are deposited in trench 1602, such as by reactively sputtering a magnetic material through a shadow mask onto semiconductor substrate 1604. Each base magnetic material layer 1802 will ultimately form the base of a respective magnetic core. The magnetic material is deposited, for example, in the presence of a uniaxial magnetic field to align the material's magnetic domains, such that the magnetic material has anisotropic magnetic properties, to help minimize magnetic hysteresis losses in the magnetic material. In some embodiments, the magnetic material forming base magnetic layers 1802 is a Co—Zr—O material having a thickness of approximately 20 microns. FIG. 19 shows a cross-sectional view taken along line 18A-18A of the FIG. 18 top plan view.

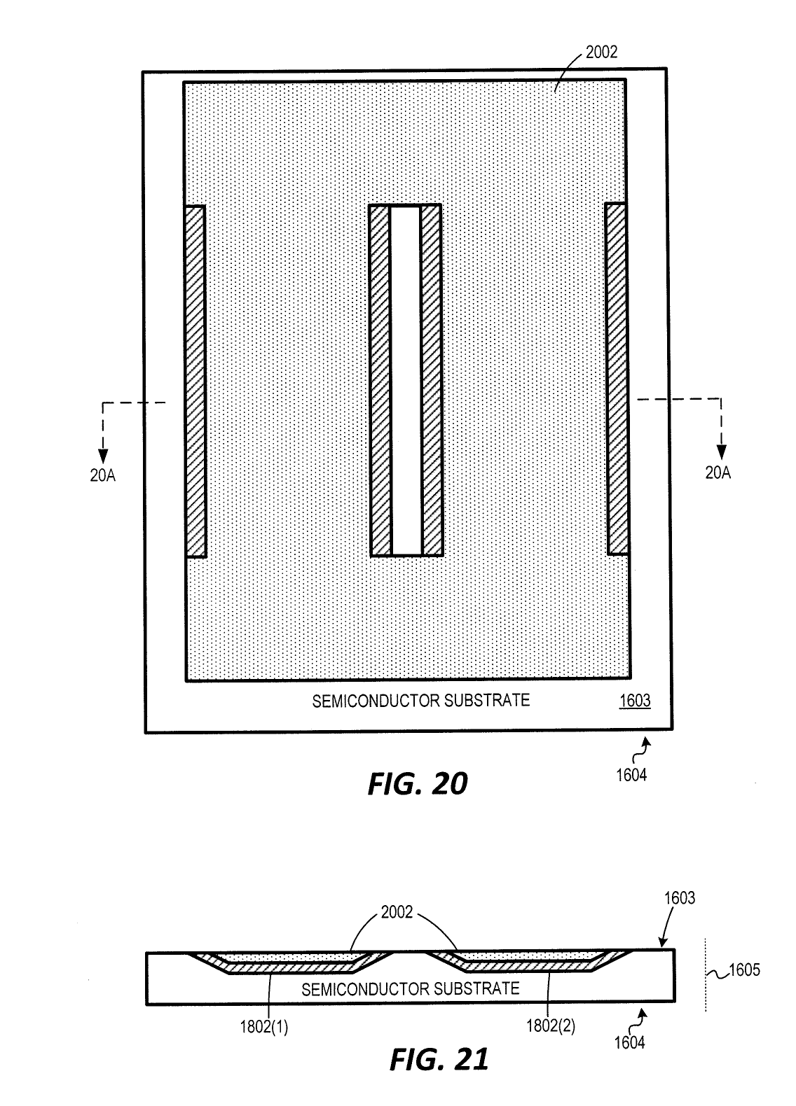

In step 1506, base insulating layer is deposited in the trench, and the semiconductor substrate outer surface is polished. In one example of step 1506, a base insulating layer 2002, which includes an epoxy-based positive photoresist material, is deposited in trench 1602, and outer surface 1603 is polished, as illustrated in FIG. 20. FIG. 21 shows a cross-sectional view taken along line 20A-20A of the FIG. 20 top plan view. In some embodiments, outer surface 1603 is polished such that the outer surface is substantially planar, as shown in FIG. 21.

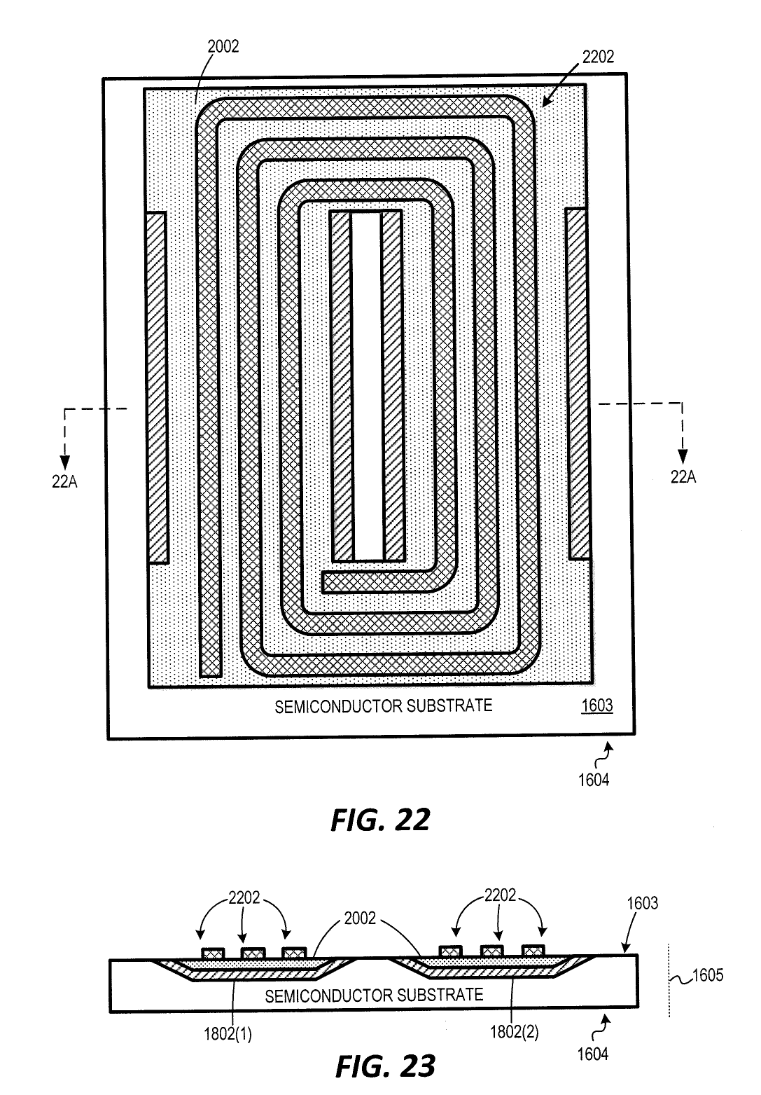

Steps 1508-1512 of method 1500 are similar to steps 106-110 of method 100 (FIG. 1). Specifically, in step 1508, an electrically conductive winding is patterned on the insulating layer. In one example of step 1508, an electrically conductive winding 2202 is patterned on insulating layer 2002, as illustrated in FIG. 22, such as by electroplating copper through a NR-21-20000P negative photoresist mold. In some embodiments, winding 2202 is 40 microns thick with 15 micron gaps between winding turns. Although winding 2202 is shown as forming three turns, winding 2202 could form a different number of turns and/or a different shape without departing from the scope hereof. FIG. 23 is a cross-sectional view taken along line 22A-22A of the FIG. 22 top plan view.

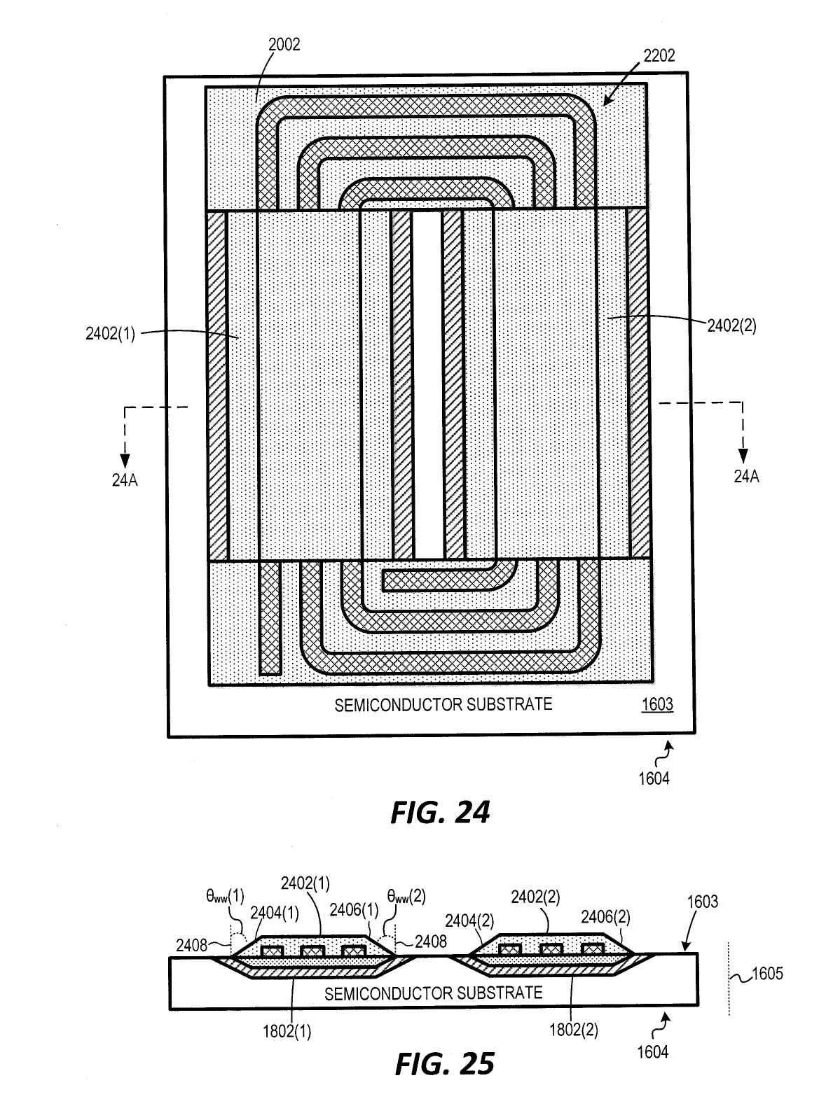

In step 1510, a top insulating structure of photoresist material is patterned over each base layer of magnetic material using a prism-assisted, ultra-violet LED photolithography procedure, such as the procedure discussed above with respect to FIGS. 12-14, to insulate the winding from a top layer of magnetic material disposed in a subsequent step. In one example of step 1510, top insulating structures 2402 having opposing sloping sidewalls 2404, 2406 are patterned on winding 2202 over base layers 1802 of magnetic material, as illustrated in FIG. 24. FIG. 25 is a cross-sectional view taken along line 24A-24A of the FIG. 24 top plan view. Each sidewall 2404, 2406 has a respective acute angle θww relative to an axis 2408 normal to outer surface 1603. In some embodiments, each angle θww is at least 30 degrees to facilitate subsequent sputter deposition of high quality magnetic material on sidewalls 2404, 2406.

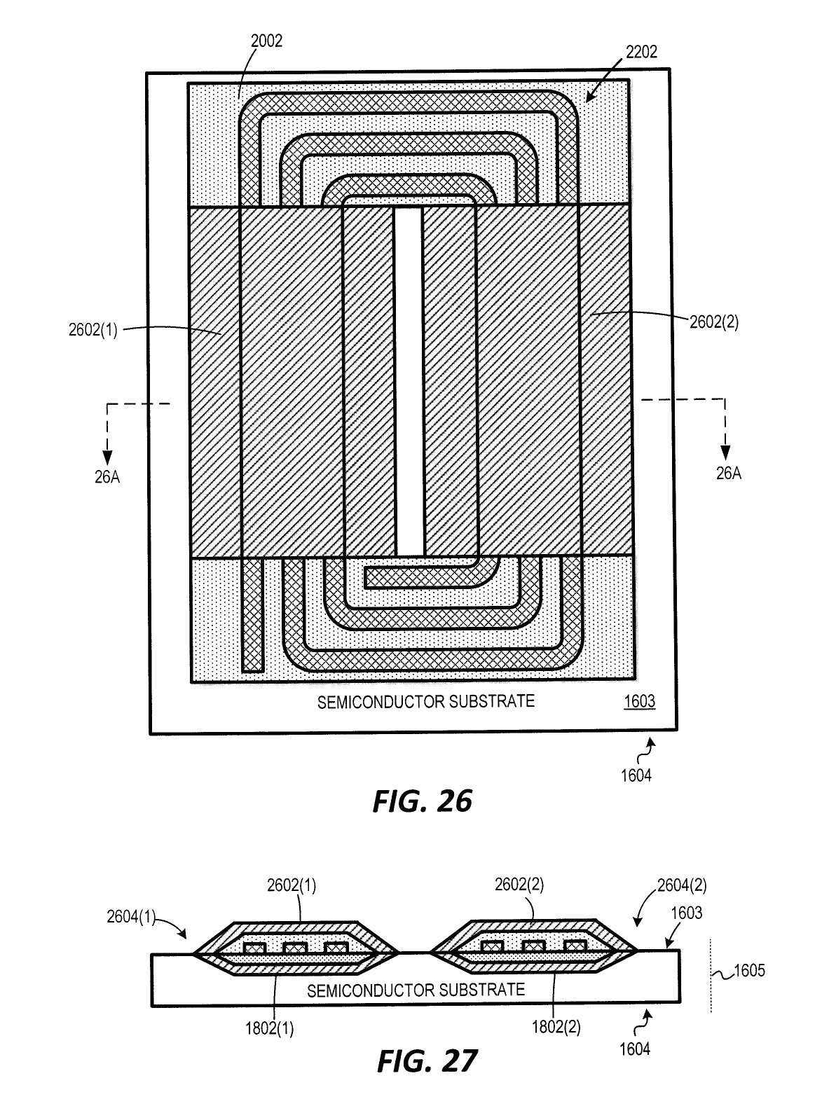

In step 1512, a top layer of magnetic material is deposited on each top insulating structure, such that the base layer of magnetic material and the top layer of magnetic material collectively form a magnetic core. In one example of step 1512, a respective top layer 2602 of magnetic material is deposited on each top insulating structure 2402, such by sputtering the magnetic material through a shadow mask onto top insulating structures 2402, as shown in FIG. 26. FIG. 27 is a cross-sectional view taken along line 26A-26A of the FIG. 26 top plan view. As shown, the inductor protrudes from outer surface 1603 of semiconductor substrate 1604. Base magnetic material layer 1802(1) and top magnetic material layer 2602(1) collectively form a first magnetic core 2604(1), and base magnetic material layer 1802(2) and top magnetic material layer 2602(2) collectively form a second magnetic core 2604(2). Each magnetic core 2604 surrounds a portion of winding 2202. Additionally, each magnetic core 2604 is partially embedded in semiconductor substrate 1604, and each magnetic core protrudes from semiconductor substrate 1604. Although magnetic cores 2604 are shown as being separated from each other, in some alternate embodiments, magnetic material joins magnetic cores 2604, such as along outer surface 1603 of semiconductor substrate 1604. In some embodiments, the magnetic material forming top magnetic material layers 2602 is a Co—Zr—O material.

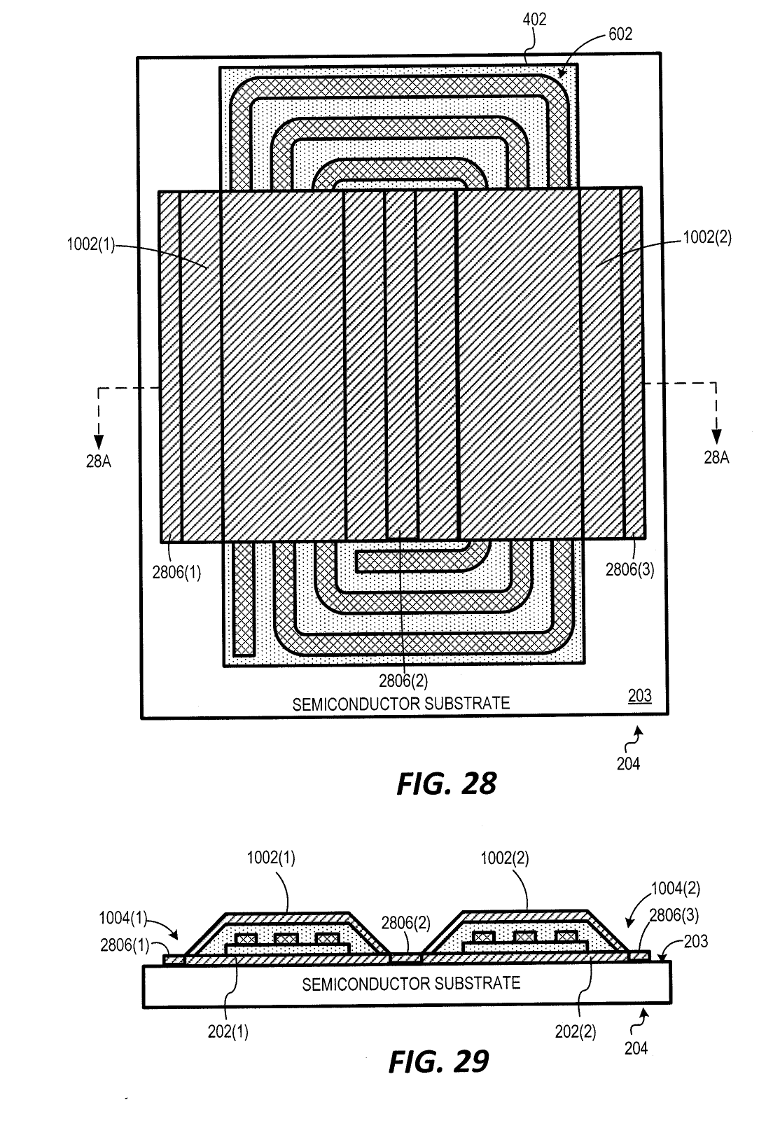

As discussed above, in some alternate embodiments of method 100 (FIG. 1), magnetic material joins magnetic cores 1004 along semiconductor substrate 204 outer surface 203. The magnetic material joining magnetic cores 1004 results, for example, from imperfect deposition of magnetic material during top layer deposition step 110. For example, FIG. 28 illustrates an example of where extraneous magnetic material 2806 accumulated on substrate outer surface 203 due to imperfect magnetic material deposition during step 110. Extraneous magnetic material 2806(2) joins magnetic cores 1004(1) and 1004(2), and extraneous magnetic material 2806(1) and 2806(3) is outside of the magnetic device. FIG. 29 is a cross-sectional view taken along line 28A-28A of the FIG. 28 top plan view. Extraneous magnetic material 2806 is typically undesirable because it provides a path for circulating eddy-currents, which contribute to magnetic device losses and heating. Extraneous magnetic material may similarly accumulate on the substrate outer surface during top magnetic layer deposition step 1512 of method 1500 (FIG. 15).

Applicants have discovered that accumulation of extraneous magnetic material during top magnetic layer deposition can be minimized by patterning shading structures on the semiconductor substrate, where the shading structures are adjacent to the top insulating structures and serve as high-resolution shadow masks to help prevent accumulation of extraneous magnetic material on the substrate surface. The shading structures are patterned, for example, concurrently with the top insulating structures to minimize fabrication steps.

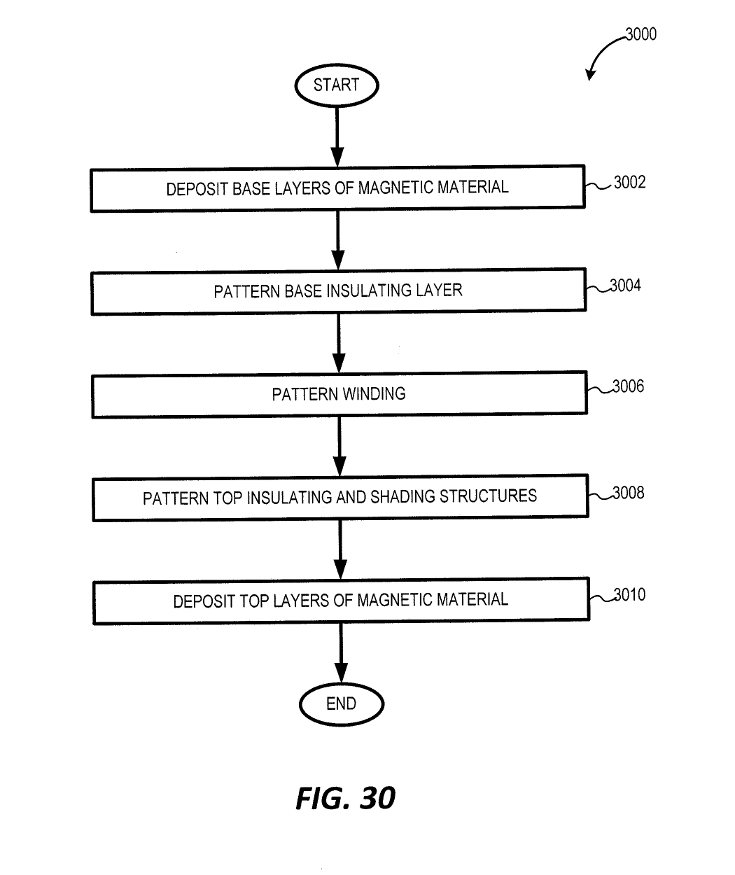

For example, FIG. 30 illustrates a method 3000 for fabricating a magnetic device, such as an inductor or transformer, on a semiconductor substrate, to form a hybrid semiconductor and magnetic device. Method 3000 is similar to method 100 of FIG. 1, but further includes patterning shading structures on the semiconductor substrate adjacent to top insulating structures, to help minimize accumulation of extraneous magnetic material. FIGS. 31-40 illustrate one example on an inductor being formed according to method 3000.

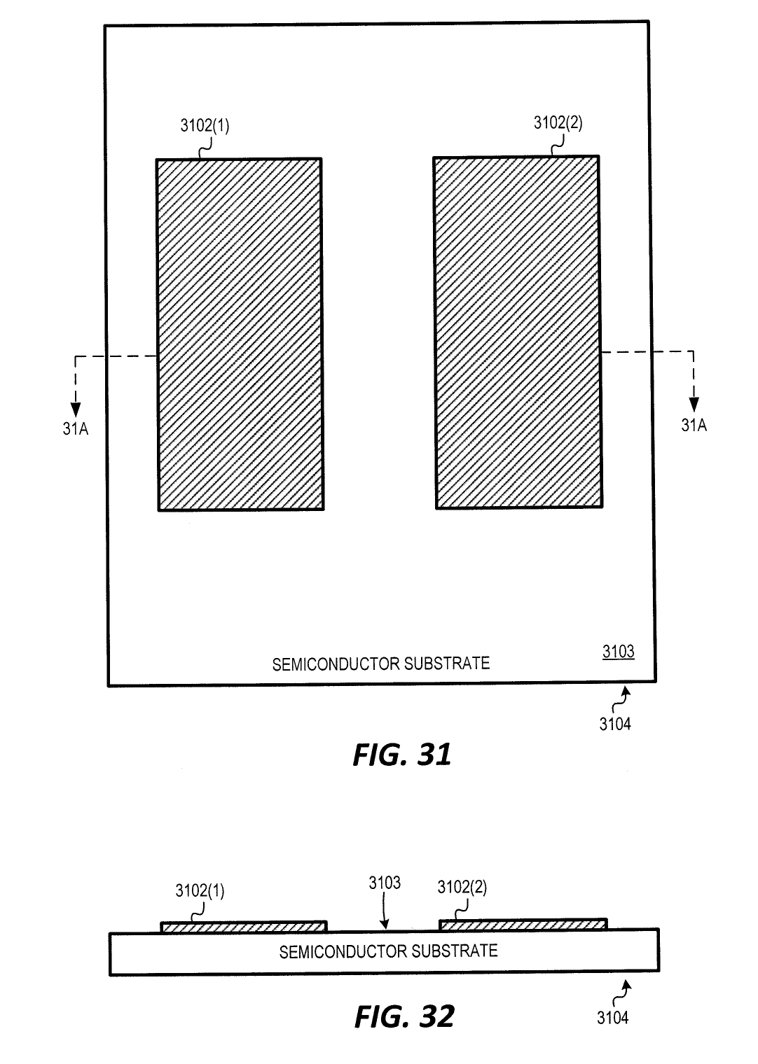

Steps 3002-3006 of method 3000 are similar to steps 102-106 of method 100 (FIG. 1). Specifically, in step 3002 of method 3000, a base layer of magnetic material is deposited on the semiconductor substrate for each magnetic core. In one example of step 3002, two base layers 3102 of magnetic material are deposited on an outer surface 3103 of a semiconductor substrate 3104 as illustrated in FIG. 31, such as by reactively sputtering a magnetic material through a shadow mask onto semiconductor substrate 3104. Each base layer 3102 will ultimately form the base of a respective magnetic core. The magnetic material is deposited, for example, in the presence of a uniaxial magnetic field to align the material's magnetic domains, such that the magnetic material has anisotropic magnetic properties, to help minimize magnetic hysteresis losses. Semiconductor substrate 3104 is typically opaque to ultraviolet light. In some embodiments, semiconductor substrate 3104 is a silicon substrate, and the magnetic material forming base layers 3102 of magnetic material is a Co—Zr—O material having a thickness of approximately 20 microns. Semiconductor substrate 3104 optionally includes one or more electronic components, such as power transistors and/or control logic. Thus, in certain embodiments, semiconductor substrate 3104 and the inductor formed thereon form part or all of a switching power converter, thereby potentially achieving a monolithically integrated power converter. FIG. 32 shows a cross-sectional view taken along line 31A-31A of the FIG. 31 top plan view.

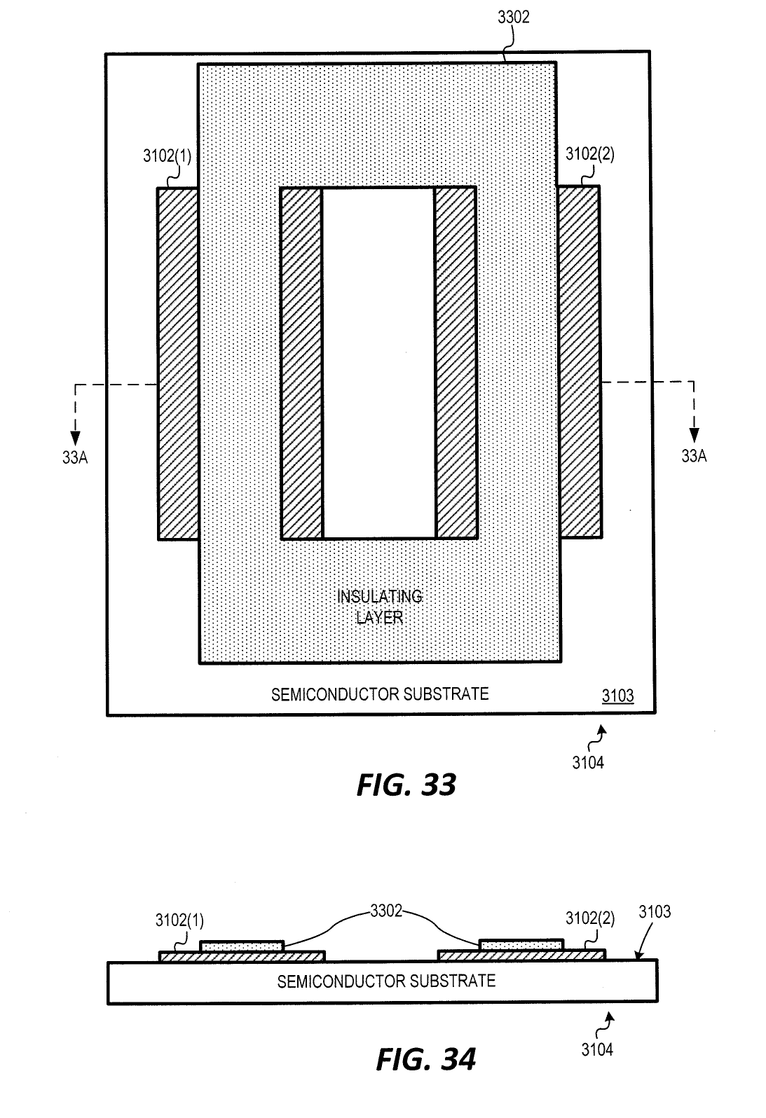

In step 3004, a base insulating layer of photoresist material is patterned on the base layers of magnetic material and on the semiconductor substrate. The base insulating layer insulates an electrically conductive winding, which is patterned in subsequent step 3006, from the base layers of magnetic material and from the semiconductor substrate. In one example of step 3004, an insulating layer 3302 is patterned on base magnetic material layers 3102 and on outer surface 3103 of semiconductor substrate 3104, as illustrated in FIG. 33. FIG. 34 is a cross-sectional view taken along line 33A-33A of the FIG. 33 top plan view. In some embodiments, insulating layer 3302 is a 20 micron thick layer of SU-8 3010 photoresist material.

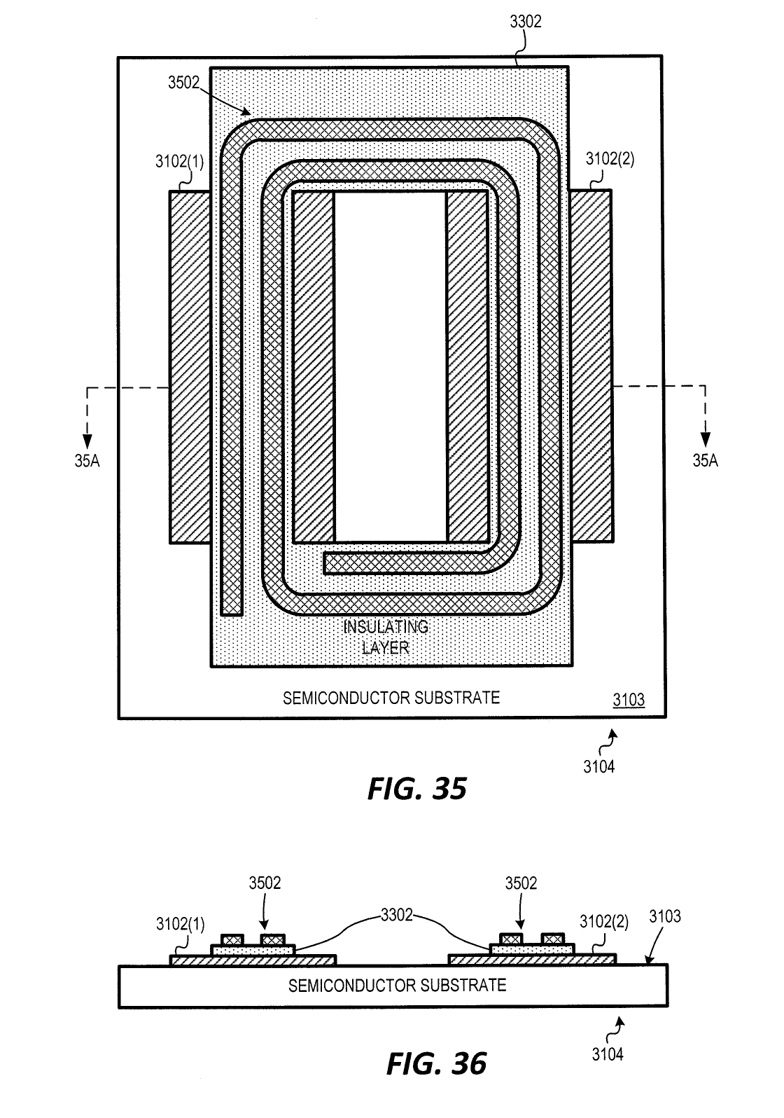

In step 3006, an electrically conductive winding is patterned on the base insulating layer. In one example of step 3006, an electrically conductive winding 3502 is patterned on insulating layer 3302, as illustrated in FIG. 35, such as by electroplating copper through a NR-21-20000P negative photoresist mold. In some embodiments, winding 3502 is 40 microns thick with 15 micron gaps between winding turns. Although winding 3502 is shown as forming two turns, winding 3502 could form a different number of turns, and/or have a different shape, without departing from the scope hereof. Additionally, in some alternate embodiments, two or more windings are formed on the insulating layer in step 3006, such as to form a transformer. FIG. 36 is a cross-sectional view taken along line 35A-35A of the FIG. 35 top plan view.

In step 3008, both top insulating structures and shading structures are patterned using a prism-assisted, ultra-violet LED photolithography procedure, such as similar to that of method 1200 discussed above. In particular, a respective top insulating structure is patterned over each base layer to insulate the winding from a top layer of magnetic material disposed in a subsequent step. The shading structures, on the other hand, are patterned on the semiconductor substrate surface and are adjacent to the top insulating structures.

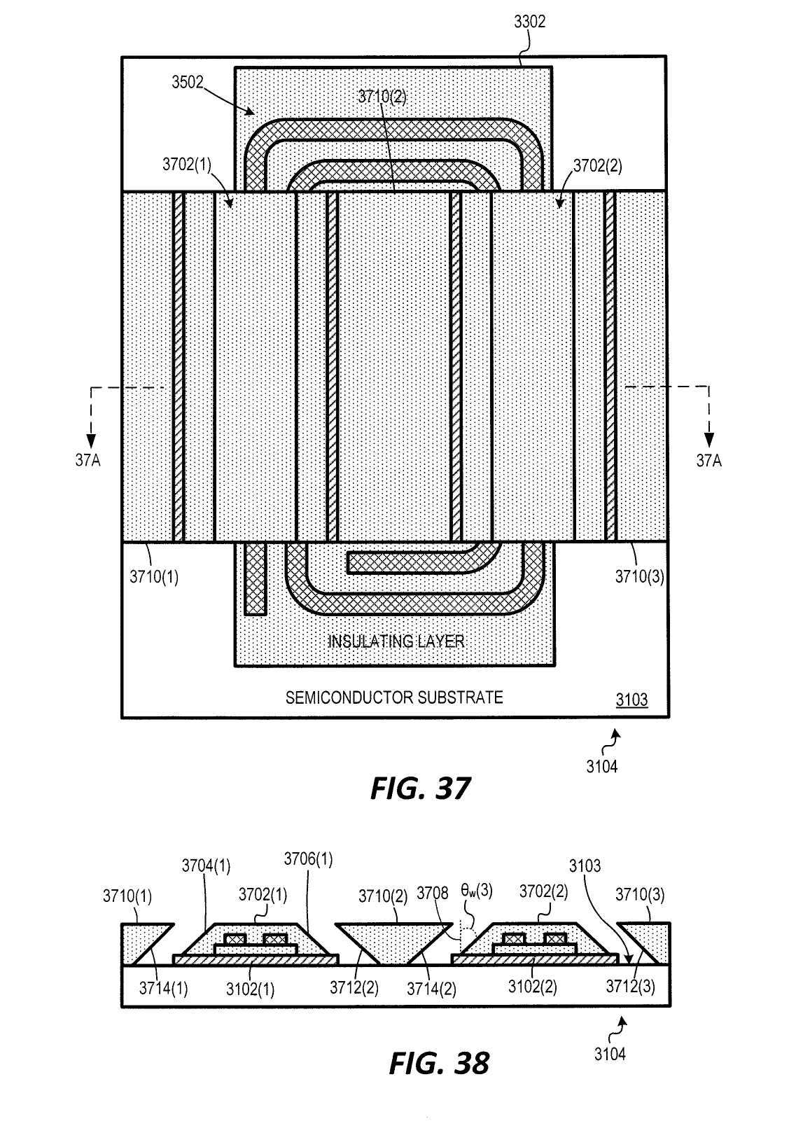

In one example of step 3008, top insulating structures 3702 and shading structures 3710 are patterned, as illustrated in FIG. 37. FIG. 38 is a cross-sectional view taken along line 37A-37A of the FIG. 37 top plan view. Top insulating structures 3702 have opposing sloping sidewalls 3704, 3706 and are patterned on winding 3502 over base layers 3102 of magnetic material, and each sidewall 3704, 3706 has a respective acute angle θw relative to an axis 3708 normal to substrate outer surface 3103. Only some instances of sloping sidewalls 3704, 3706 and angles θw are labeled to promote illustrative clarity. In some embodiments, each angle θw is at least 30 degrees to facilitate subsequent sputter deposition of high quality magnetic material on sidewalls 3704, 3706. Shading structures 3710 are patterned on substrate outer surface 3103 adjacent to top insulating structures 3702, and shading structures 3710 have opposing sloping sidewalls 3712, 3714. In some embodiments, sloping sidewalls 3712 are substantially parallel to sloping sidewalls 3706, and sloping sidewalls 3714 are substantially parallel to sloping sidewalls 3704.

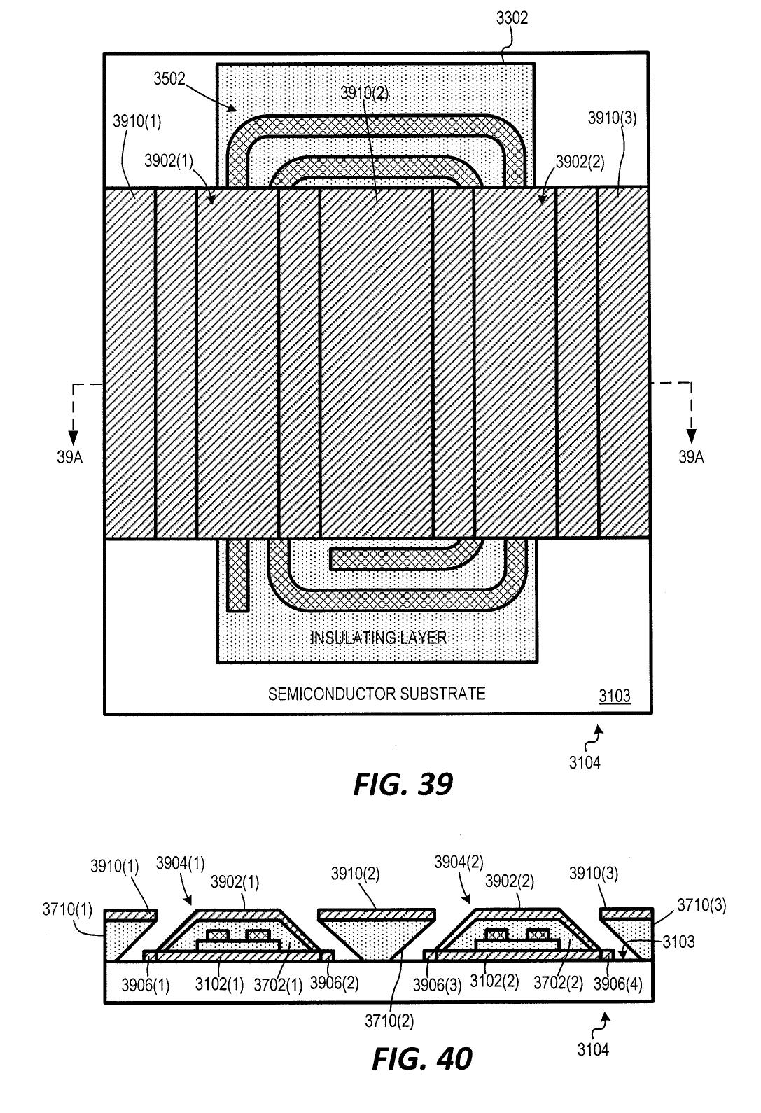

In step 3010, a top layer of magnetic material is deposited on each top insulating structure, such that the base layer of magnetic material and the top layer of magnetic material collectively form a magnetic core surrounding the winding. In one example of step 3010, a respective top magnetic layer 3902 is deposited on each top insulating structure 3702 by sputtering the magnetic material through a shadow mask (not shown) onto the top insulating structure, as illustrated in FIG. 39. FIG. 40 is a cross-sectional view taken along line 39A-39A of the FIG. 39 top plan view. Base magnetic material layer 3102(1) and top magnetic material layer 3902(1) collectively form a first magnetic core 3904(1), and base magnetic material layer 3102(2) and top magnetic material layer 3902(2) collectively form a second magnetic core 3904(2). Each magnetic core 3904 surrounds a portion of winding 3502. In some embodiments, the magnetic material forming top magnetic material layers 3902 is a Co—Zr—O material.

Shading structures 3710 significantly block magnetic material from reaching substrate 3104 during step 3010. Accordingly, relatively little extraneous magnetic material 3906 accumulates on substrate outer surface 3103, as illustrated. Some extraneous magnetic material 3910 will also accumulate on top surfaces of shading structures 3710, as illustrated. Magnetic material 3910, however, typically will not significantly negatively impact inductor operation.

Method 1500 of FIG. 15 could be modified to further included patterning shading structures, such as in a manner similar to that discussed above with respect to method 3000 of FIG. 30. For example, in an alternate embodiment of method 1500, step 1510 is modified to pattern both top insulating and shading structures using a prism-assisted, ultra-violet LED photolithography procedure, such as similar to that of method 1200 discussed above. The shading structures in this alternate embodiment of method 1500, for example, are similar to shading structures 3710 discussed above.

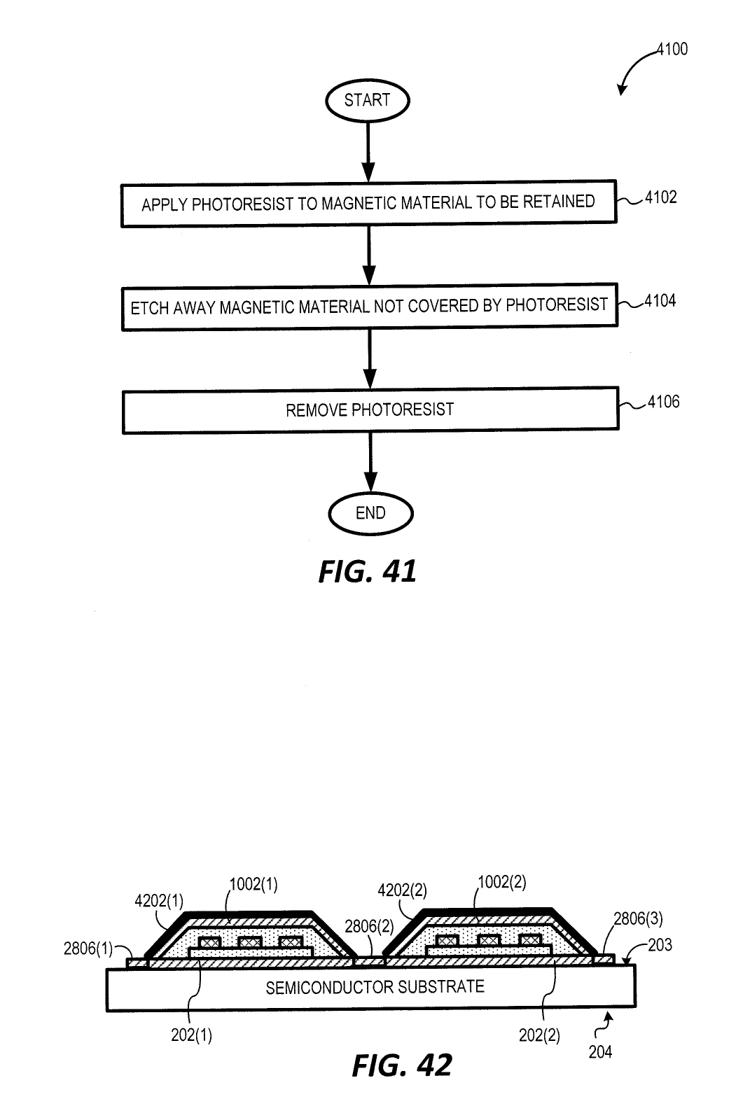

Applicants have also determined that losses can be further minimized by removing extraneous magnetic material after depositing the top layers of magnetic material, e.g., after step 110 of method 100, after step 1512 of method 1500, and after step 3010 of method 30. Extraneous magnetic material is removed, for example, by method 4100 illustrated in FIG. 41. Method 4100 is discussed below in conjunction with the example of FIG. 29, discussed above, where extraneous magnetic material 2806 accumulated on substrate outer surface 203 after execution of step 110 of method 100. Method 4100, however, could be executed after the completion of any one of methods 100, 1500, or 3000 without departing from the scope hereof.

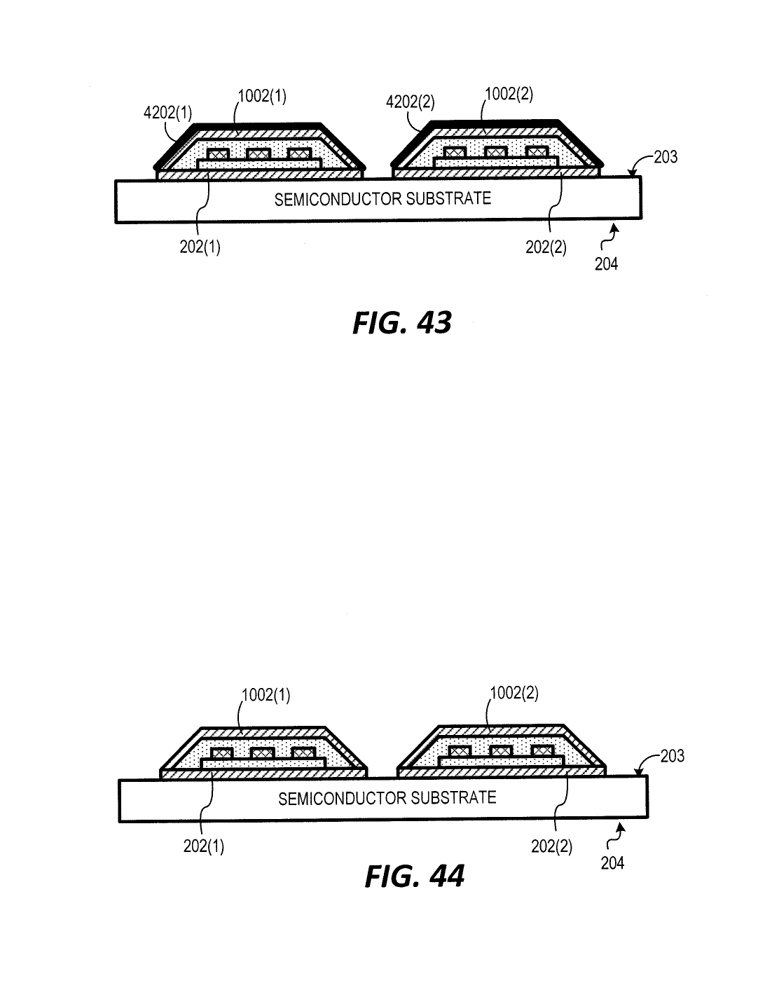

In step 4102 of method 4100, photoresist is applied to magnetic material to be retained, such as by spray coating or spin coating. In one example of step 4102, positive photoresist 4202 is applied to top magnetic layers 1002, but not to extraneous magnetic material 2806, as illustrated in FIG. 42. In step 4104, magnetic material not covered by photoresist is etched away, thereby removing extraneous magnetic material. In one example of step 4104, extraneous magnetic material not covered by photoresist 4202 is etched away, as illustrated in FIG. 43. In step 4106, the photoresist is removed. In one example of step 4106, photoresist 4202 is removed, as illustrated in FIG. 44.

Combinations of Features

(A1) A method for exposing a photoresist material to light may include the following steps: (1) optically coupling the light to an optical mask via a prism and a first liquid layer joining the prism and the optical mask; (2) masking the light using the optical mask; and (3) optically coupling the masked light to the photoresist material.

(A2) In the method denoted as (A1), the step of optically coupling the masked light to the photoresist material may include optically coupling the masked light to the photoresist material via a second liquid layer joining the optical mask and the photoresist material.

(A3) In the method denoted as (A2), the first liquid layer may include water, and the second liquid layer may include an oil having a surface tension lower than that of water.

(A4) In the method denoted as (A1), the step of optically coupling the masked light to the photoresist material may include directly contacting the photoresist material with the optical mask.

(A5) The method denoted as (A4) may further include compressing the photoresist material via the optical mask.

(A6) In any of the methods denoted as (A1) through (A5): (1) the prism may include first and second faces; (2) the first liquid layer may join the second face of the prism and the optical mask; and (3) the step of optically coupling the light to the optical mask may include projecting the light onto the first face of the prism.

(A7) In the method denoted as (A6): (1) the prism further may include a third face; and (2) the step of optically coupling the light to the optical mask may further include projecting the light onto the third face of the prism, after projecting the light onto the first face of the prism.

(A8) In the method denoted as (A6): (1) the prism may further include a third face; and (2) the step of optically coupling the light to the optical mask may further include simultaneously projecting the light onto the first and third faces of the prism.

(A9) In any of the methods denoted as (A6) through (A8), the photoresist material may be disposed between the second face of the prism and an opaque substrate.

(A10) In any of the methods denoted as (A1) through (A9), the light may be ultraviolet light.

(A11) The method denoted as (A10) may further include generating the light using an array of light emitting diodes.

(B1) A method for fabricating a magnetic device on a semiconductor substrate may include the following steps: (1) depositing a base layer of magnetic material on the semiconductor substrate; (2) patterning a base insulating layer on the base layer of magnetic material; (3) patterning a winding on the base insulating layer; (4) optically coupling light to an optical mask via a prism and a first liquid layer joining the prism and the optical mask; (5) masking the light using the optical mask; (6) optically coupling the masked light to photoresist material disposed on the winding; (7) developing the photoresist material to yield a top insulating structure; and (8) depositing a top layer of magnetic material on the top insulating structure.

(B2) In the method denoted as (B1), the step of optically coupling the masked light to photoresist material may include optically coupling the masked light to photoresist material via a second liquid layer joining the optical mask and the photoresist material.

(B3) In the method denoted as (B2), the first liquid layer may include water, and the second liquid layer may include an oil having a surface tension lower than that of water.

(B4) In the method denoted as (B1), the step of optically coupling the masked light to photoresist material may include directly contacting the photoresist material with the optical mask.

(B5) The method denoted as (B4) may further include compressing the photoresist material via the optical mask.

(B6) In any of the methods denoted as (B1) through (B5): (1) the prism may include first and second faces; (2) the first liquid layer may join the second face of the prism and the optical mask; and (3) the step of optically coupling the light to the optical mask may include projecting the light onto the first face of the prism.

(B7) In the method denoted as (B6): (1) the prism may further include a third face; and (2) the step of optically coupling the light to the optical mask may further include projecting the light onto the third face of the prism, after directing the light onto the first face of the prism.

(B8) In the method denoted as (B6): (1) the prism may further include a third face; and (2) the step of optically coupling the light to the optical mask may further include simultaneously projecting the light onto the first and third faces of the prism.

(B9) In any of the methods denoted as (B1) through (B8), the light may be ultraviolet light.

(B10) The method denoted as (B9) may further include generating the light using an array of light emitting diodes.

(B11) Any of the methods denoted as (B1) through (B10) may further include etching a trench in the semiconductor substrate, and the step of depositing the base layer of magnetic material on the semiconductor substrate may include depositing the base layer of magnetic material at least partially in the trench.

(B12) In the method denoted as (B11), the step of depositing the base insulating layer on the base layer of magnetic material may include depositing the base insulating layer in the trench.

(B13) The method denoted as (B12) may further include polishing an outer surface of the semiconductor substrate, prior to the step of patterning the winding on the base insulating layer.

(B14) Any of the methods denoted as (B1) through (B13) may further include, after the step of optically coupling the masked light to photoresist material and before the step of depositing the top layer of magnetic material, developing the photoresist material to further yield a shading structure adjacent to the top insulating structure.

(B15) Any of the methods denoted as (B1) through (B14) may further include, after the step of depositing the top layer of magnetic material: (1) applying photoresist to the top layer of magnetic material; (2) etching away extraneous magnetic material; and (3) removing the photoresist.

(C1) A hybrid semiconductor and magnetic device may include: (1) a semiconductor substrate; (2) a top insulating structure deposited on an outer surface of the semiconductor substrate, the top insulating structure having opposing first and second sloping sidewalls, each sloping sidewall forming an acute angle of at least 30 degrees, relative to an axis normal to the outer surface of the semiconductor substrate; and (3) a magnetic core surrounding the top insulating structure.

(C2) In the device denoted as (C1), the magnetic core may be partially embedded in the semiconductor substrate.

(C3) In the device denoted as (C2), the magnetic core may protrude from the outer surface of semiconductor substrate.

(C4) In any of the devices denoted as (C1) through (C3), the magnetic core may be formed of a material including Co—Zr—O.

(C5) In any of the devices denoted as (C1) through (C4), the semiconductor substrate may be a silicon substrate.

(C6) Any of the devices denoted as (C1) through (C5) may further include a shading structure disposed on the outer surface of the semiconductor substrate adjacent to the top insulating structure, the shading structure having opposing third and fourth sloping sidewalls, the third sloping sidewall being substantially parallel to the second sloping sidewall, and the fourth sloping sidewall being substantially parallel to the first sloping sidewall.

Changes may be made in the above methods and systems without departing from the scope hereof. It should thus be noted that the matter contained in the above description and shown in the accompanying drawings should be interpreted as illustrative and not in a limiting sense. The following claims are intended to cover generic and specific features described herein, as well as all statements of the scope of the present method and system, which, as a matter of language, might be said to fall therebetween.

1. A method for exposing a photoresist material to light, comprising:
optically coupling the light to an optical mask via a prism and a first liquid layer joining the prism and the optical mask;
masking the light using the optical mask; and
optically coupling the masked light to the photoresist material;
the step of optically coupling the masked light to the photoresist material comprising optically coupling the masked light to the photoresist material via a second liquid layer joining the optical mask and the photoresist material, and
the first liquid layer comprising water, and the second liquid layer comprising an oil having a surface tension lower than that of water.

2-5. (canceled)

6. The method of claim 1, wherein:
the prism comprises first and second faces;
the first liquid layer joins the second face of the prism and the optical mask; and
the step of optically coupling the light to the optical mask comprises projecting the light onto the first face of the prism.

7. The method of claim 6, wherein:
the prism further comprises a third face; and
the step of optically coupling the light to the optical mask further comprises projecting the light onto the third face of the prism.

8. (canceled)

9. The method of claim 6, the photoresist material being disposed between the second face of the prism and an opaque substrate.

10. The method of claim 1, the light being ultraviolet light.

11. (canceled)

12. A method for fabricating a magnetic device on a semiconductor substrate, comprising:
depositing a base layer of magnetic material on the semiconductor substrate;
patterning a base insulating layer on the base layer of magnetic material;
patterning a winding on the base insulating layer;
optically coupling light to an optical mask via a prism and a first liquid layer joining the prism and the optical mask;
masking the light using the optical mask;
optically coupling the masked light to photoresist material disposed on the winding;
developing the photoresist material to yield a top insulating structure; and
depositing a top layer of magnetic material on the top insulating structure.

13. The method of claim 12, the step of optically coupling the masked light to photoresist material comprising optically coupling the masked light to photoresist material via a second liquid layer joining the optical mask and the photoresist material.

14. The method of claim 13, the first liquid layer comprising water, and the second liquid layer comprising an oil having a surface tension lower than that of water.

15. The method of claim 12, the step of optically coupling the masked light to photoresist material comprising directly contacting the photoresist material with the optical mask.

16. The method of claim 15, further comprising compressing the photoresist material via the optical mask.

17. The method of claim 12, wherein:
the prism comprises first and second faces;
the first liquid layer joins the second face of the prism and the optical mask; and
the step of optically coupling the light to the optical mask comprises projecting the light onto the first face of the prism.

18. The method of claim 17, wherein:
the prism further comprises a third face; and
the step of optically coupling the light to the optical mask further comprises projecting the light onto the third face of the prism, after directing the light onto the first face of the prism.

19. The method of claim 17, wherein:
the prism further comprises a third face; and
the step of optically coupling the light to the optical mask further comprises simultaneously projecting the light onto the first and third faces of the prism.

20. The method of claim 12, the light being ultraviolet light.

21. The method of claim 20, further comprising generating the light using an array of light emitting diodes.

22. The method of claim 12, further comprising:
etching a trench in the semiconductor substrate;
wherein the step of depositing the base layer of magnetic material on the semiconductor substrate comprises depositing the base layer of magnetic material at least partially in the trench.

23. The method of claim 22, wherein the step of depositing the base insulating layer on the base layer of magnetic material comprises depositing the base insulating layer in the trench.

24. The method of claim 23, further comprising polishing an outer surface of the semiconductor substrate, prior to the step of patterning the winding on the base insulating layer.

25. The method of claim 12, further comprising, after the step of optically coupling the masked light to photoresist material and before the step of depositing the top layer of magnetic material, developing the photoresist material to further yield a shading structure adjacent to the top insulating structure.

26. The method of claim 12, further comprising, after the step of depositing the top layer of magnetic material:
applying photoresist to the top layer of magnetic material;
etching away extraneous magnetic material; and
removing the photoresist.

27-32. (canceled)
